(19) United States
(12) Patent Application Publication
(10) Pub. No.: US 2025/0323135 A1
(43) Pub. Date: Oct. 16, 2025

(54) SEMICONDUCTOR PACKAGE

(71) Applicant: LG INNOTEK CO., LTD., Seoul (KR)

(72) Inventors: Hye Jin JO, Seoul (KR); Won Suk JUNG, Seoul (KR); Byong Ryul LEE, Seoul (KR)

(73) Assignee: LG INNOTEK CO., LTD., Seoul (KR)

(21) Appl. No.: 18/291,466

(22) PCT Filed: Jul. 22, 2022
(86) PCT No.: PCT/KR2022/010835

§ 371 Date: Jul. 30, 2024

(30) Foreign Application Priority Data
Jul. 23, 2021 (KR) 10-2021-0097391

(51) Int. Cl. H01L 23/498; H01L 23/00; H01L 23/29; H01L 23/31; H01L 23/538; H01L 25/18; H05K 1/02; H05K 1/11; H05K 1/18; H05K 3/00; H05K 3/46; H10B 80/00; H10D 80/30

(52) U.S. Cl. CPC H01L 23/49838; H01L 23/3121; H01L 23/3135; H01L 23/49894; H01L 23/5385; H01L 23/5386; H01L 23/5389; H01L 25/18; H05K 1/0298; H05K 1/111; H05K 1/181; H10B 80/00; H01L 23/29; H01L 24/16; H01L 24/32; H01L 24/48; H01L 24/73; H01L 2224/16227; H01L 2224/32145; H01L 2224/32225; H01L 2224/48145; H01L 2224/48225; H01L 2224/73204; H01L 2224/73215; H01L 2224/73265; H01L 2225/06506; H01L 2225/0651; H01L 2225/06517; H01L 2225/06524; H01L 2225/06568; H01L 2924/1432; H05K 3/0026; H05K 3/4644; H10D 80/30

(57) ABSTRACT

A semiconductor package according to an embodiment includes a first insulating layer; a first circuit pattern disposed on the first insulating layer and including a first pad; a first molding layer disposed on an upper surface of the first insulating layer; a through electrode including a first conductive coupling part disposed on the first pad and having a first width and a through part disposed on the first conductive coupling part and having a second width smaller than the first width, and passing through of the first molding layer; and a second conductive coupling part disposed on the through part of the through electrode; wherein the first width of the first conductive coupling part is smaller than a third width of the second conductive coupling part.

### TECHNICAL FIELD

The embodiment relates to a semiconductor package.

### BACKGROUND ART

High performance of electric/electronic products is progressing, and accordingly, techniques for attaching a larger number of packages to a substrate having a limited size have been proposed and studied. However, a typical package is based on a single semiconductor chip mounted thereon, and there is a limit in obtaining desired performance by this.

A typical semiconductor package has a form in which a processor package in which a processor chip is disposed and a memory package to which a memory chip is attached are connected as one. Such a semiconductor package has advantages of reducing a chip mounting area and enabling high-speed signals through a short pass by manufacturing a processor chip and a memory chip into one integrated package.

Due to these advantages, the semiconductor package as described above is widely applied to mobile devices and the like.

On the other hand, recently, the size of the package is increasing due to the high specification of electronic devices such as mobile devices and the adoption of High Bandwidth Memory (HBM). Accordingly, a semiconductor package including an interposer is mainly used. At this time, the interposer is composed of a silicon substrate.

However, in the case of an interposer such as a silicon substrate, there is a problem in that the material cost for manufacturing the interposer is high, and the formation of a through silicon via (TSV) is complicated and the cost is high.

Also, conventionally, a substrate including a silicon-based interconnect bridge is used as a semiconductor package. However, in the case of a silicon-based interconnect bridge, there is a reliability issue due to a CTE (Coefficient of Thermal Expansion) mismatch between the silicon material of the bridge and the organic material of the substrate, and there is a problem in that the power integrity characteristic is deteriorated.

### DISCLOSURE

### Technical Problem

The embodiment provides a circuit board having a novel structure and a semiconductor package including the same.

In addition, the embodiment provides a circuit board on which a plurality of processor chips can be mounted side by side and a semiconductor package including the same.

In addition, the embodiment provides a circuit board including a through electrode formed using a wire and a semiconductor package including the same.

The technical problem to be solved in the embodiment is not limited to the technical problem mentioned above, and another technical problem not mentioned will be clearly understood by those of ordinary skill in the art to which the present invention belongs from the following description.

### Technical Solution

A semiconductor package according to an embodiment includes a first insulating layer; a first circuit pattern disposed on the first insulating layer and including a first pad; a first molding layer disposed on an upper surface of the first insulating layer; a through electrode including a first conductive coupling part disposed on the first pad and having a first width and a through part disposed on the first conductive coupling part and having a second width smaller than the first width, and passing through of the first molding layer; and a second conductive coupling part disposed on the through part of the through electrode; wherein the first width of the first conductive coupling part is smaller than a third width of the second conductive coupling part.

In addition, the through electrode includes a reinforcing part disposed between the first conductive coupling part and the through part.

In addition, the reinforcing part has a fourth width greater than the second width of the through part and smaller than the first width of the first conductive coupling part.

In addition, the reinforcing part has a width ranging between 110% and 150% of a width of the through part.

In addition, an upper surface of the first conductive coupling part includes a concave part concave toward the first pad, and wherein at least a part of the reinforcing part is disposed on the concave part of the first conductive coupling part.

In addition, the first conductive coupling part, the reinforcing part, and the through part are provided with the same metal material as each other, and wherein a lower surface of the first conductive coupling part is in contact with the first pad.

In addition, a height from a lower surface to an upper surface of the through electrode is in the range of 50 μm to 200 μm, and wherein the through part has a width in a range of 10 μm to 100 μm.

In addition, the height of the through electrode is greater than 100 μm, and wherein a width of the through part is greater than 40 μm.

In addition, a straightness corresponding to an inclined angle of the through part with respect to the virtual vertical line is 10 degrees or less.

In addition, the semiconductor package further includes a second insulating layer disposed on an upper surface of the first insulating layer and including an opening overlapping an upper surface of the first pad in a vertical direction; and wherein the through electrode is disposed on the upper surface of the first pad overlapping the opening of the second insulating layer in a vertical direction.

In addition, the first width of the first conductive coupling part of the through electrode is smaller than a width of the opening of the second insulating layer, and wherein the first molding layer covers at least a part of the first conductive coupling part and at least a part of the reinforcement part of the through electrode, and fills at least a part of the opening of the second insulating layer.

In addition, the semiconductor package further includes a second circuit pattern disposed under a lower surface of the first insulating layer and including a second pad; a third insulating layer disposed under a lower surface of the first insulating layer and having an opening overlapping at least a part of a lower surface of the second pad in a vertical direction; and a third conductive coupling part disposed under a lower surface of the second pad overlapping the opening of the third insulating layer in a vertical direction; and wherein a size of the third conductive coupling part is larger than a size of the first and second conductive coupling parts.

In addition, the semiconductor package further includes third and fourth pads disposed on an upper surface of the first insulating layer and spaced apart from the first pad in a width direction; wherein the first molding layer includes a first cavity overlapping at least a part of an upper surface of the third pad and at least a part of an upper surface of the fourth pad in a vertical direction; wherein a first chip is mounted on the third pad overlapping the first cavity in a vertical direction; wherein a second chip is mounted on the fourth pad overlapping the first cavity in a vertical direction; and wherein a second molding layer is disposed in the first cavity and covering the first chip and the second chip.

In addition, the first molding layer and the second molding layer include different insulating materials.

In addition, the first chip corresponds to a central processor (CPU), and wherein the second chip corresponds to a graphics processor (GPU).

In addition, the first insulating layer includes a second cavity overlapping at least a part of a lower surface of the third pad and at least a part of a lower surface of the fourth pad in a vertical direction; wherein a fourth conductive coupling part is disposed on a lower surface of the third pad and a lower surface of the fourth pad overlapping the second cavity in a vertical direction; wherein a bridge substrate is disposed in the second cavity and connected to the first pad and the second pad through the fourth conductive coupling part; and wherein the bridge substrate connects at least one terminal of the first chip connected to the first pad and at least one terminal of the second chip connected to the second pad.

In addition, side and lower surfaces of the first pad are covered by the first insulating layer.

In addition, the first insulating layer comprises a first layer comprising a first insulating material including glass fibers and a second layer comprising a second insulating material different from the first insulating material which does not contain glass fibers.

In addition, the first layer comprises a prepreg, and wherein the second layer comprises a resin coated copper (RCC).

In addition, the semiconductor package further includes a memory substrate disposed on the second conductive coupling part; a memory chip mounted on the memory substrate; and a third molding layer disposed on the memory substrate and covering the memory chip.

### Advantageous Effects

The circuit board of the embodiment includes a first insulating layer and a second insulating layer. The first insulating layer includes a prepreg, and the second insulating layer includes RCC. The embodiment minimizes the number of layers of the first insulating layer including the prepreg, and configures the circuit board by using the number of the second insulating layers including the RCC. Accordingly, the embodiment may reduce the overall thickness of the circuit board by using the second insulating layer while improving the overall warpage characteristics of the circuit board by using the first insulating layer. Accordingly, the embodiment may slim the circuit board, and further slim the semiconductor package.

In addition, the embodiment includes a first circuit pattern having an ETS structure on an upper surface of the first insulating layer. In addition, the first circuit pattern includes first and second pads on which chips are mounted. In this case, upper surfaces of the first and second pads are used as mounting pads on which the first and second chips are mounted, lower surfaces of the first pad and the second pad overlap the first cavity in a vertical direction, and thus may be used as a terminal pad on which a bridge substrate is mounted.

Accordingly, the embodiment can reduce the signal transmission distance between the chip and the bridge substrate by arranging both the chip and the bridge substrate using a single pad, and accordingly, signal transmission loss can be minimized.

In addition, the embodiment allows the first circuit pattern to have an ETS structure and to be supported through a portion of the first insulating layer including the prepreg. Accordingly, a problem of physical reliability of the first pad and the second pad that may occur as the first cavity vertically overlaps with the first pad and the second pad (e.g., exposed through the first cavity) can be solved, and thereby improving product reliability.

In addition, although a general semiconductor package includes a bridge substrate, the bridge substrate is disposed in a state in which it is embedded in the circuit board. For example, a bridge substrate in a conventional semiconductor package is embedded in a circuit board, and thus has a structure in which an insulating layer and a circuit pattern are disposed on and below the circuit board. However, the bridge substrate in the case of such a structure may be bent according to the bending characteristics of the circuit board, and thus reliability of the bridge substrate may be deteriorated. For example, a crack may occur in the bridge substrate due to a difference between the coefficient of thermal expansion of the circuit board and the coefficient of thermal expansion of the bridge substrate, and accordingly, damage to the ultrafine circuit layer included in the bridge substrate may occur. On the other hand, the bridge substrate of the embodiment may be disposed in a first cavity of the circuit board and protected by a first molding layer. Furthermore, an insulating layer or circuit patterns constituting the circuit board are not disposed under the bridge substrate. Accordingly, the embodiment may maintain reliability by improving the bending characteristics of the bridge substrate in various usage environments of the circuit board, thereby improving communication performance between a first processor chip and a second processor chip. In addition, heat generated from the bridge substrate can be easily radiated to the outside by allowing at least a portion of the bridge substrate of the embodiment to be exposed to the outside of the first molding layer, and thereby increasing heat dissipation of the bridge substrate. Furthermore, the embodiment may improve the reliability of the bridge substrate, and thereby improving the performance of signal transmission or power transmission between the first processor chip and the second processor chip connected through the bridge substrate.

In addition, the embodiment includes a second molding layer including a second cavity while protecting the through electrode on an upper side of the circuit board and a third molding layer disposed in the second cavity of the second molding layer to mold a chip. In addition, the second molding layer and the third molding layer in the embodiment have different strengths from each other.

Accordingly, the through electrode and the chip in the embodiment may be stably protected by forming the second and third molding layers of different materials. In addition, damage to the circuit board in the embodiment can be protected by the manufacturing process of the circuit board in a state in which the second molding layer is formed when the bridge substrate is mounted, and further improve the reliability of the connection between the circuit board and the bridge substrate.

In addition, the through electrode in the embodiment may be a wire part formed by bonding a metal wire. To this end, the through electrode may include a first conductive coupling part, a reinforcing part, and a through part. In this case, the through electrode according to the embodiment includes a through part corresponding to the metal wire, and thus a width of the through electrode may be reduced. Accordingly, spacing and pitch between the plurality of through electrodes in the embodiment may be reduced, and further, a width of the circuit board in a horizontal direction may be reduced, and thus the degree of integration of the circuit board may be improved.

In addition, the through electrode in the embodiment includes a first conductive coupling part, thereby increasing the bonding force between the third pad and the through part, and furthermore, it is possible to reduce a signal loss caused by a difference between a width of the third pad and a width of the through part. For example, when the through part is directly disposed on the third pad, the bonding force between the third pad and the through part may decrease, so that the through part may be detached from the third pad. In addition, when the through part is disposed directly on the third pad and a signal is transmitted between the third pad and the through part, signal loss may occur due to a sudden change in a width between the third pad and the through part. In this case, the embodiment can solve the above problems by forming the first conductive coupling part between the third pad and the through part, and accordingly, electrical reliability and physical reliability of the circuit board may be improved.

In addition, the through electrode of the embodiment includes a reinforcing part disposed between the first conductive coupling part and the through part. The reinforcing part may have a predetermined height on the first conductive coupling part and may have a greater width than the through part. Accordingly, the through part of the embodiment can be stably supported through the reinforcing part, so that straightness of the through electrode can be improved, and thus electrical reliability of the through electrode can be improved.

### DESCRIPTION OF DRAWINGS

FIG. 1 is a cross-sectional view illustrating a semiconductor package according to a comparative example.

FIG. 2 is a cross-sectional view showing a circuit board according to a first embodiment.

FIG. 3 is a view for explaining a partial configuration of FIG. 2.

FIG. 4 is a view specifically illustrating a layer structure of a circuit pattern constituting a first insulating layer of FIG. 3.

FIG. 5 is a view for explaining a pad of a first circuit pattern of FIG. 3.

FIG. 6 is a view for explaining a through electrode of FIG. 2.

FIG. 7 is a view showing a bridge substrate of FIG. 2.

FIG. 8 is a view showing a detailed structure of a redistribution layer of a bridge substrate of FIG. 7.

FIG. 9 is a view showing a circuit board according to a second embodiment, and FIG. 10 is a view showing a bridge substrate of FIG. 9.

FIGS. 11A to 11W are views for explaining a circuit board of FIG. 2 in order of process.

FIG. 12 is a view illustrating a first semiconductor package according to an embodiment.

FIG. 13 is a view illustrating a second semiconductor package according to an embodiment.

FIG. 14 is a view illustrating a third semiconductor package according to an embodiment.

### MODES OF THE INVENTION

Hereinafter, embodiments of the present invention will be described in detail with reference to the accompanying drawings.

However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms may be construed the same meaning as commonly understood by one of ordinary skill in the art to which this invention belongs, and the terms such as those defined in commonly used dictionaries may be interpreted as having a meaning that is consistent with their meaning in the context of the relevant art. Further, the terms used in the embodiments of the present invention are for describing the embodiments and are not intended to limit the present invention.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present invention, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements. Further, when expressed as “on (over)” or “under (below)”, it may include not only the upper direction but also the lower direction based on one element.

### Comparative Example

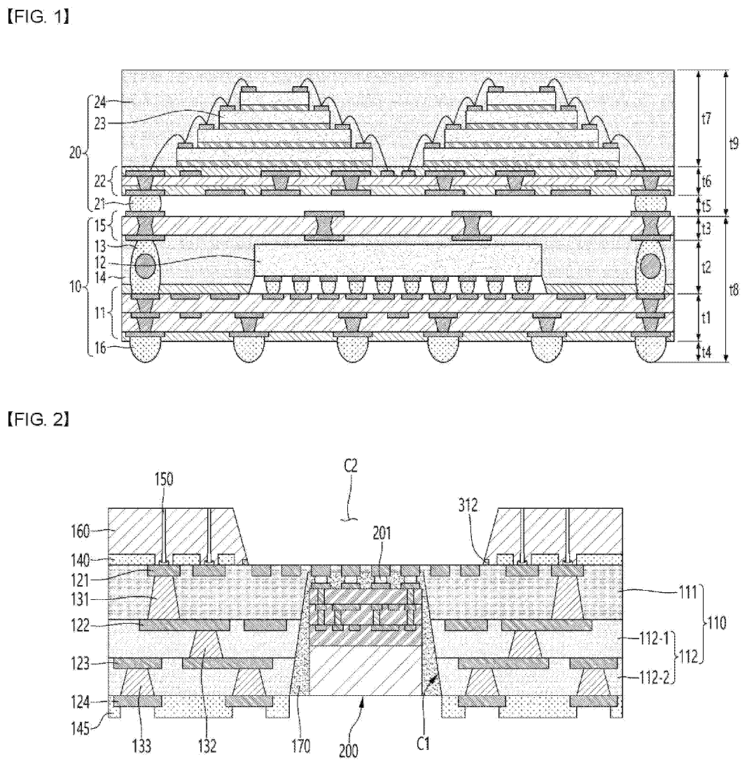

FIG. 1 is a cross-sectional view illustrating a semiconductor package according to a comparative example.

Referring to FIG. 1, at least two packages in the comparative example are required in order to transmit a signal to a main board of an electronic device.

A semiconductor package included in the electronic device in the comparative example may be in a state in which at least two or more packages are combined.

The semiconductor package according to the comparative example includes a first package 10 and a second package 20.

The first package 10 is a processor package on which the processor chip 12 is mounted. In addition, the second package 20 is a memory package in which the memory chip 23 is mounted.

The first package 10 includes a first substrate 11 on which the processor chip 12 is mounted. The first substrate 11 has a multilayer structure, and includes one side portion on which the processor chip 12 is disposed and the other side portion on which a first adhesive ball 16 is disposed. The first package 10 has a fan-out structure and is attached to a main board (not shown) of an electronic device using a first adhesive ball 16 disposed on the other side.

A processor chip 12 is mounted on the first substrate 11. The processor chip 12 is an integrated processor chip in which various functions are integrated. Accordingly, the size of the processor chip 12 increases in proportion to the number of functions provided. That is, the first substrate 11 has a processor chip 12 mounted thereon, and has a function of connecting the processor chip 12 and the main board of the electronic device.

Meanwhile, the first package 10 of the comparative example further includes a second substrate 15. The second substrate 15 is an interposer that interconnects the first package 10 and the second package 20.

That is, the semiconductor package of the comparative example essentially includes an interposer such as the second substrate 15. In addition, the semiconductor package in the comparative example has a problem in that the overall volume increases in proportion to a thickness of the interposer. Accordingly, the thickness of the electronic device in the semiconductor package of the comparative example increases, and accordingly, there is a limit to slimming.

In addition, the semiconductor package in the comparative example uses the second substrate 15 to interconnect the first package 10 and the second package 20, so that a length of the signal transmission line increases. That is, the comparative example semiconductor package must pass through at least the second substrate 15 in order to transmit the signal of the processor chip 12 and the signal of the memory chip 23 to each other, and accordingly, the signal transmission distance between the processor chip 12 and the memory chip 23 increases to correspond to the length of the signal transmission line in the second substrate 15. Accordingly, in the comparative example, high-speed communication between the processor chip 12 and the memory chip 23 is difficult due to the second substrate 15. Furthermore, the comparative example is vulnerable to noise as the signal transmission distance by the second substrate 15 increases, and accordingly, there is a problem in that communication performance is reduced.

Meanwhile, the first package 10 of the comparative example includes a second adhesive ball 13 disposed on a first substrate 11 and a first molding layer 14 molding the second adhesive ball 13 and the processor chip 12. In this case, the first molding layer 14 protects the processor chip 12 and the second adhesive ball 13. Accordingly, a thickness of the first molding layer 14 is determined by the height of the processor chip 12 and the second adhesive ball 13. However, the second substrate of the comparative example 15 is additionally disposed on the first molding layer 14, accordingly, the thickness of the first molding layer 14 must also consider the influence of the second substrate 15, and thus there is a problem in that the thickness increases.

In addition, the second package 20 of the comparative example includes a third substrate 22, a memory chip 23 disposed on the third substrate 22, and a second molding layer 24.

As described above, in the comparative example, at least three substrates are required to electrically connect the processor chip 12 and the memory chip 23 to each other. In addition, in the comparative example, a process for bonding at least three substrates to each other is required, and accordingly, there is a problem in that the yield decreases due to the increase in the number and complexity of the manufacturing process. Specifically, the comparative example requires at least three substrates due to the difficulty of the process of arranging different chips on one substrate.

In addition, at least two adhesive balls in the comparative example are required to bond at least three substrates to each other.

That is, in the comparative example, the second adhesive ball 13 for connecting the first substrate 11 and the second substrate 15 and the third adhesive balls 21 for connecting the second substrate 15 and the third substrate 22 are required. Accordingly, since the semiconductor package according to the comparative example requires at least two or more adhesive balls for mutual bonding of a plurality of substrates, there is a problem in that reliability of the semiconductor package may be deteriorated due to poor connection of the adhesive balls. In addition, it has a structure in which the two or more adhesive balls are disposed in the thickness direction, and the thickness of the semiconductor package and the thickness of the electronic device increase by the thickness of the adhesive balls.

Specifically, the first substrate 11 has a first thickness t1 of 120 μm to 150 μm. A second thickness t2 including the first molding layer 14, the processor chip 12, and the second adhesive ball 13 is 145 μm to 160 μm. In addition, the third thickness t3 of the second substrate 15 is 90 μm to 110 μm. In addition, the fourth thickness t4 of the first adhesive ball 16 is 130 μm to 150 μm.

Accordingly, a total thickness t8 of the first package 10 including the first to fourth thicknesses t1, t2, t3, and t4 is 480 μm to 550 μm.

In addition, the fifth thickness t5 of the third adhesive ball 21 is 145 μm to 180 μm. In addition, the sixth thickness t6 of the third substrate 22 is 90 μm to 110 μm. In addition, the seventh thickness t7 including the memory chip 23 and the second molding layer 24 is 370 μm to 400 μm. Accordingly, the total thickness t9 of the second package 20 including the fifth to seventh thicknesses t5, t6, and t7 is 610 μm to 700 μm. Accordingly, the overall thickness of the semiconductor package of the comparative example is 1100 μm or more.

Meanwhile, a required thickness of the semiconductor package is 1100 μm or less due to slimming of electronic devices. In addition, the type of electronic device in recent years is mainly composed of foldable products, and the restriction in a longitudinal direction is small while the restriction in a thickness direction is large due to the characteristics of the foldable product. However, the semiconductor package of the comparative example has a structure in which a plurality of substrates are bonded to each other via a plurality of adhesive balls in the thickness direction, and accordingly, there is a problem in that the specifications required by the electronic device are not satisfied.

In addition, as the performance of electric/electronic products is progressing recently, techniques for attaching a larger number of packages to a substrate having a limited size are being studied, and accordingly, miniaturization of circuit patterns is required. However, in the case of the semiconductor package of the comparative example, there is a limit to the miniaturization of the circuit pattern. The circuit pattern included in the semiconductor package of the comparative example has a line width of at least 10 μm and an interval of 10 μm or more. In addition, as functions processed by an application processor (AP) increase in recent years, it is becoming difficult to implement them in a single chip. However, in the case of the circuit pattern provided in the comparative example, it is difficult to mount two application processors AP having different functions on the one first substrate 11.

Furthermore, the second substrate 15 must be included to match the pitch of the pad between the first substrate 11 and the third substrate 22, and there is a problem in that the overall thickness of the semiconductor package increases as much as the thickness of the second substrate 15.

The embodiment is intended to solve the problems of the comparative example, and it is possible to provide a circuit board having a new structure on which a plurality of application processor chips can be mounted on one substrate and a semiconductor package including the same.

Furthermore, the embodiment is to solve the problems of this comparative example, the second substrate 15 may be removed by realizing a fine pitch using a through electrode, and accordingly, it is possible to provide a circuit board having a new structure and a semiconductor package including the same to achieve slimming, miniaturization, and high integration of the semiconductor package.

### —Electronic Device—

Before describing the embodiment, an electronic device including the semiconductor package of the embodiment will be briefly described. The electronic device includes a main board (not shown). The main board may be physically and/or electrically connected to various components. For example, the main board may be connected to the semiconductor package of the embodiment. Various chips may be mounted on the semiconductor package. Broadly, memory chips such as volatile memory (e.g. DRAM), non-volatile memory (e.g. ROM), flash memory, and the like, an application processor chip such as a central processor (e.g., CPU), a graphics processor (e.g., GPU), a digital signal processor, an encryption processor, a microprocessor, and a microcontroller, and a logic chip such as an analog-to-digital converter or an application-specific IC (ASIC) may be mounted on the semiconductor package.

Further, the embodiment provides a semiconductor package capable of mounting at least two different types of chips on one substrate while reducing the thickness of the semiconductor package connected to the main board of the electronic device. Accordingly, the embodiment may facilitate signal or power transmission between a plurality of chips, thereby achieving miniaturization of an electronic device.

In this case, the electronic device may be a smart phone, a personal digital assistant, a digital video camera, a digital still camera, a network system, computer, a monitor, a tablet, a laptop, a netbook, a television, a video game, a smart watch, an automotive, or the like. However, the embodiment is not limited thereto, and in addition to these, any other electronic device for processing data may be included.

### Embodiment

Hereinafter, a circuit board according to an embodiment and a semiconductor package including the circuit board will be described in detail.

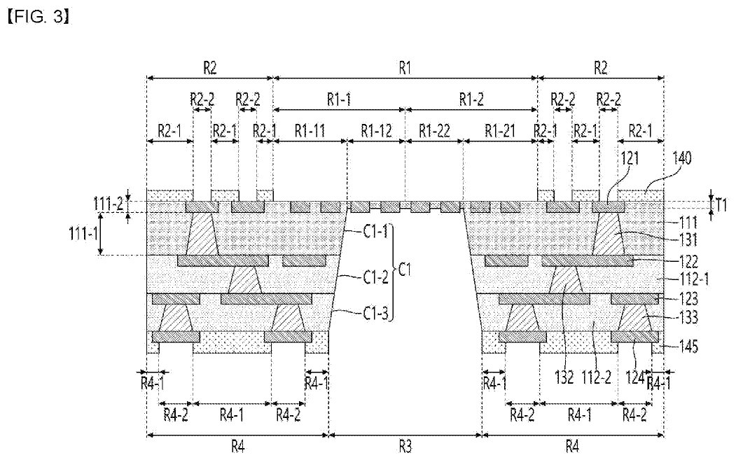

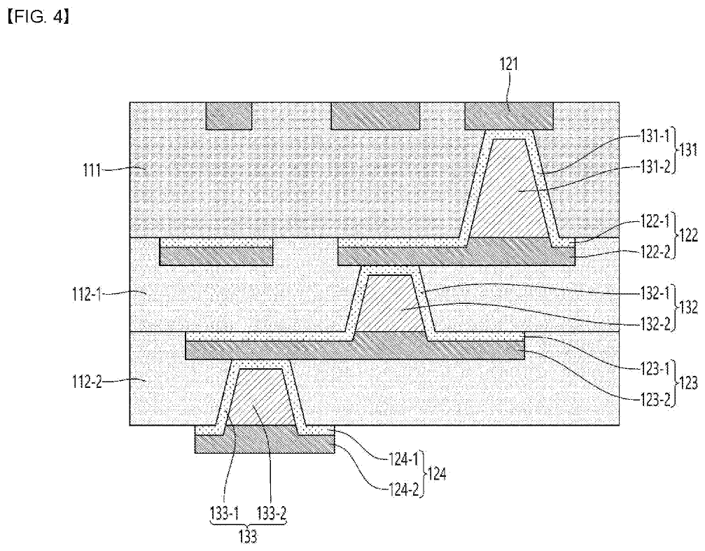

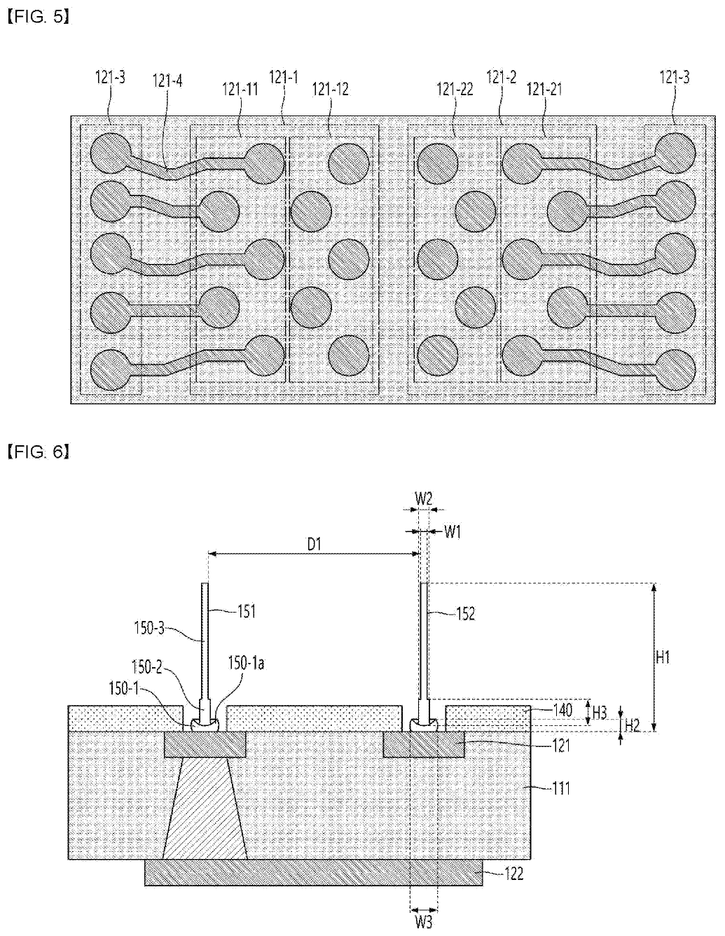

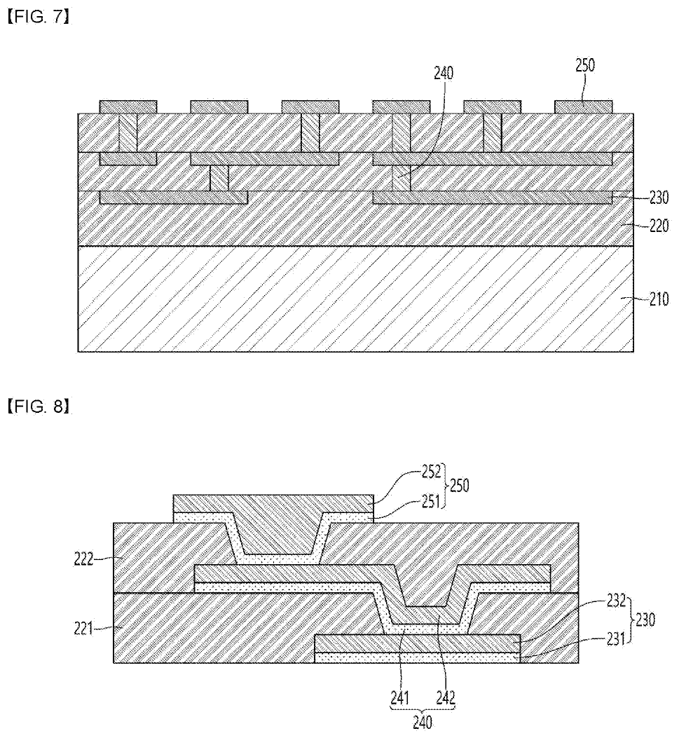

FIG. 2 is a cross-sectional view showing a circuit board according to a first embodiment, FIG. 3 is a view for explaining a partial configuration of FIG. 2, FIG. 4 is a view specifically illustrating a layer structure of a circuit pattern constituting a first insulating layer of FIG. 3, FIG. 5 is a view for explaining a pad of a first circuit pattern of FIG. 3, FIG. 6 is a view for explaining a through electrode of FIG. 2, FIG. 7 is a view showing a bridge substrate of FIG. 2, and FIG. 8 is a view showing a detailed structure of a redistribution layer of a bridge substrate of FIG. 7.

Hereinafter, the circuit board according to the first embodiment will be described in detail with reference to FIGS. 2 to 8.

Referring to FIGS. 2 to 8, the circuit board includes an insulating layer 110.

In this case, a plurality of insulating layers in the embodiment may include a first insulating layer 111 including a first insulating material and a second insulating layer 112 including a second insulating material different from the first insulating material.

The circuit board according to the first embodiment allows at least two different chips to be mounted thereon. For example, the circuit board according to the first embodiment may include a plurality of chips on which at least two processor chips may be mounted. For example, the circuit board may include a first mounting region in which the CPU is mounted and a second mounting region in which the GPU is mounted. In this case, the first mounting region and the second mounting region may be formed on an outermost side of the circuit board, and may be arranged side by side in a width direction rather than a thickness direction. For example, the circuit board in the embodiment allows the CPU and GPU to be mounted side by side at positions spaced apart from each other by a predetermined distance.

The first insulating layer 111 may have a one-layer structure. However, the embodiment is not limited thereto, and the first insulating layer 111 may have a layer structure of at least two or more layers. However, the embodiment allows a thickness of the first package in the comparative example to be slimmed down. In this case, the first insulating layer 111 has a greater thickness than the second insulating layer 112 described below. Accordingly, in the embodiment, the number of layers of the first insulating layer 111 is minimized and the number of layers of the second insulating layer 112 can be increased according to a circuit layout design in order to slim the circuit board.

The first insulating layer 111 may provide a chip mounting region in which a chip is mounted.

The circuit board of the embodiment includes the second insulating layer 112 disposed on a second surface or a lower surface of the first insulating layer 111. The second insulating layer 112 may be composed of one layer, or alternatively, may have a multilayer structure of two or more layers. In this case, in the embodiment, to enable signal transmission between a chip such as a memory or a processor and a main board of an electronic device, circuit patterns for this should be arranged. And, to this end, when the second insulating layer 112 is composed of only one layer, it may be difficult to arrange all of the circuit patterns. Accordingly, the second insulating layer 112 in the embodiment has two or more layers. However, the embodiment is not limited thereto.

An outermost side of the second insulating layer 112 may be connected to the main board of the electronic device, and may include a terminal pad region for connecting to the main board.

The first insulating layer 111 may include a first insulating material. For example, the first insulating layer 111 may be made of a resin including reinforcing fibers. For example, the first insulating layer 111 may include a prepreg.

That is, the circuit board of the embodiment can improve the warpage characteristics while slimming the overall thickness. Furthermore, it is necessary to provide a mounting region in which at least two processor chips can be mounted.

In this case, when an entire insulating layer of the circuit board includes the same second insulating material as the second insulating layer 112, the overall thickness of the circuit board may be reduced, but reliability may decrease accordingly. For example, when the entire insulating layer of the circuit board includes a second insulating material such as the second insulating layer 112, cracks easily occur in the circuit board, and the warpage characteristic may be deteriorated, and furthermore, there may be a problem in that the chip mounting pad on which the chip is mounted cannot be stably supported.

Accordingly, at least one insulating layer among the plurality of insulating layers constituting the circuit board in the embodiment is configured with the first insulating layer 111 including the first insulating material in order to solve the above problems. Furthermore, a cavity C1 and C2 in the embodiment is formed in the circuit board, and the cavity overlaps the first and second surfaces of the mounting pad disposed on an uppermost side of the circuit board in a vertical direction. For example, first surface and the second surface of the mounting pad disposed on the uppermost side of the circuit board may be disposed in the cavity and exposed through the cavity. Here, being exposed means that the first and second surfaces of the mounting pad are exposed to a configuration other than the mounting pad, and does not mean that they are exposed to an outside of the semiconductor package. In this case, when the insulating layer supporting the mounting pad is the second insulating layer 112, the physical reliability of the mounting pad may decrease in the process of forming the cavity C1 and C2. For example, the second insulating layer 112 may have a lower strength than the first insulating layer 111. Accordingly, when the mounting pad is supported by the second insulating layer 112, there is a problem in that the mounting pad is separated from the insulating layer or a problem in that a flatness of the mounting pad is deteriorated.

Accordingly, a mounting pad for mounting the chip in the embodiment may be disposed on the first insulating layer 111. This will be described in more detail below.

In an embodiment, the first insulating layer 111 may include a prepreg including reinforcing fibers, and accordingly, a mounting region in which the at least two processor chips can be mounted is provided while improving the bending characteristics of the circuit board.

That is, the prepreg may be formed by impregnating a fiber layer in the form of a fabric sheet, such as a glass fabric woven with glass yarn, with an epoxy resin, and then performing thermocompression. However, the embodiment is not limited thereto, and the prepreg constituting the insulating layer 111 may include a fiber layer in the form of a fabric sheet woven with carbon fiber yarn.

Specifically, the insulating layer 111 may include a resin and a reinforcing fiber disposed in the resin. The resin may be an epoxy resin, but is not limited thereto. The resin is not particularly limited to the epoxy resin, and for example, one or more epoxy groups may be included in the molecule, or alternatively, two or more epoxy groups may be included, or alternatively, four or more epoxy groups may be included. In addition, the resin of the insulating layer 110 may include a naphthalene group, for example, may be an aromatic amine type, but is not limited thereto. For example, the resin may be include a bisphenol A type epoxy resin, a bisphenol F type epoxy resin, a bisphenol S type epoxy resin, a phenol novolac type epoxy resin, an alkylphenol novolac type epoxy resin, a biphenyl type epoxy resin, an aralkyl type epoxy resin, dicyclopentadiene type epoxy resin, naphthalene type epoxy resin, naphthol type epoxy resin, epoxy resin of condensate of phenol and aromatic aldehyde having phenolic hydroxyl group, biphenyl aralkyl type epoxy resin, fluorene type epoxy resin resins, xanthene-type epoxy resins, triglycidyl isocyanurate, rubber-modified epoxy resins, phosphorous-based epoxy resins, and the like, and naphthalene-based epoxy resins, bisphenol A-type epoxy resins, and phenol novolac epoxy resins, cresol novolak epoxy resins, rubber-modified epoxy resins, and phosphorous-based epoxy resins. In addition, the reinforcing fiber may include glass fiber, carbon fiber, aramid fiber (e.g., aramid-based organic material), nylon, silica-based inorganic material or titania-based inorganic material. The reinforcing fibers may be arranged in the resin to cross each other in a planar direction.

Meanwhile, the glass fiber, carbon fiber, aramid fiber (e.g., aramid-based organic material), nylon, silica-based inorganic material or titania-based inorganic material may be used.

Meanwhile, the first insulating layer 111 is disposed on uppermost or lowermost side of the circuit board. However, for convenience of description, it is assumed that the first insulating layer 111 is disposed on an uppermost side of the circuit board. An uppermost side of the circuit board may correspond to a region in which a chip is mounted. For example, the first insulating layer 111 may refer to an insulating layer disposed on the uppermost side of the plurality of insulating layers constituting the circuit board.

The first insulating layer 111 may have a thickness in a range of 10 μm to 30 μm. For example, the first insulating layer 111 may satisfy a range of 15 μm to 25 μm. For example, the first insulating layer 111 may satisfy a range of 18 μm to 23 μm. When the thickness of the first insulating layer 111 is less than 10 μm, the glass fibers disposed in the first insulating layer 111 protrude to an outside of the surface of the first insulating layer 111, and thus a problem may occur in electrical reliability. In addition, when the thickness of the first insulating layer 111 is greater than 30 μm, the overall thickness of the circuit board increases, and accordingly, it may be difficult to slim the semiconductor package.

The thickness of the first insulating layer 111 may correspond to a distance between a circuit pattern and a circuit pattern. For example, the thickness of the first insulating layer 111 may mean a distance between a lower surface of a first circuit pattern 121 and an upper surface of a second circuit pattern 122.

A second insulating layer 112 is disposed on the second surface of the first insulating layer 111. The second insulating layer 112 may have two layers as described above.

The second insulating layer 112 may include a second insulating material different from the first insulating material constituting the first insulating layer 111. For example, the second insulating layer 112 may be made of a resin that does not include glass fibers. For example, the second insulating layer 112 may be resin coated copper (RCC).

For example, the second insulating layer 112 may include a second-first insulating layer 112-1 disposed on a second surface or a lower surface of the first insulating layer 111 and the second-second insulating layer 112-2 disposed on a second surface or a lower surface of the second-first insulating layer 112-1. In addition, each of the second-first insulating layer 112-1 and the second-second insulating layer 112-2 may include RCC.

Each of the second-first insulating layer 112-1 and the second-second insulating layer 112-2 may have a thickness smaller than a thickness of the first insulating layer 111.

For example, each of the second-first insulating layer 112-1 and the second-second insulating layer 112-2 may have a thickness of 8 μm to 20 μm. For example, each of the second-first insulating layer 112-1 and the second-second insulating layer 112-2 may have a thickness of 8.5 μm to 17 μm. For example, each of the second-first insulating layer 112-1 and the second-second insulating layer 112-2 may have a thickness of 9 μm to 15 μm. When the thickness of the second-first insulating layer 112-1 and the second-second insulating layer 112-2 is less than 8 μm, the circuit pattern may not be stably protected by the second-first insulating layer 112-1 and the second-second insulating layer 112-2. When the thickness of the second-first insulating layer 112-1 and the second-second insulating layer 112-2 is greater than 20 μm, the overall thickness of the circuit board increases, and accordingly, it may be difficult to slim the semiconductor package.

The thickness of the second-first insulating layer 112-1 may mean a distance between a lower surface of the second circuit pattern 122 and an upper surface of the third circuit pattern 123. Also, the thickness of the second-second insulating layer 112-2 may mean a distance between a lower surface of the third circuit pattern 123 and an upper surface of the fourth circuit pattern 124.

In the embodiment, the remaining insulating layers except for the first insulating layer 111 of a single layer are composed of RCC in the insulating layer 110 constituting the circuit board, and it allows for improved signal or power transfer performance while reducing the overall thickness of the circuit board.

That is, the second insulating layer 112 in the embodiment is made of RCC having a low dielectric constant, and accordingly, it is possible to provide a highly reliable circuit board that minimizes signal loss even in a high frequency band while reducing the thickness of the circuit board.

Meanwhile, the second insulating layer 112 is not limited to the RCC, and may be composed of another insulating layer including an insulating material that does not include glass fibers. For example, the second insulating layer 112 may include a photocurable resin or a photosensitive resin. For example, the second insulating layer 112 may include photo imageable dielectric (PID).

An uppermost side of the first insulating layer 111 corresponding to a first outermost side of the circuit board as described above may include a chip mounting region in which a plurality of chips are mounted. For example, an uppermost side of the first insulating layer 111 may include a first region R1 in which a chip is mounted and a second region R1 other than the chip mounting region R1.

In addition, the first region R1 may include a first-first region R1-1 in which the first chip is mounted, and a first-second region R1-2 in which the second chip is mounted. Also, the first-first region R1-1 and the first-second region R1-2 may be divided into a plurality of regions, respectively. The first-first region R1-1 may include a first-first sub region R1-11 and a first-second sub region R1-12. The first-second region R1-2 may include a second-first sub region R1-21 and a second-second sub region R1-22.

That is, the first chip and the second chip include terminals to be electrically connected to each other. For example, the first chip includes a first-first terminal to be electrically connected to the second chip, and a first-second terminal other than the first-first terminal. In addition, the second chip includes a second-first terminal electrically connected to the first chip and a second-second terminal other than the second-first terminal.

And, the first-first sub-region R1-11 is a region in which a mounting pad connected to the first-second terminal among the terminals of the first chip is disposed, and the first-second sub-region R1-12 is a region in which a mounting pad connected to the first-first terminal among the terminals of the first chip is disposed.

Correspondingly, the second-first sub region R1-21 is a region in which mounting pads connected to the second-second terminal among the terminals of the second chip are disposed, and the second-second sub region R1-22 is a region in which a mounting pad connected to the second-first terminal among the terminals of the second chip is disposed.

In addition, a first protective layer 140 to be described later may be disposed in the second region R2 of the first insulating layer 111. In this case, the first protective layer 140 may include an opening. For example, the first protective layer 140 may include an opening that is vertically overlapped with a first surface or upper surface of the first circuit pattern 121 disposed on a first surface or an upper surface of the first insulating layer 111.

Accordingly, the second region R2 of the first insulating layer 111 may include a second-first region R2-1 in which the first protective layer 140 is disposed and a second-second region R2-2 corresponding to the opening of the first protective layer 140.

In addition, a second surface of the second insulating layer 112 may include a third region R3 and a fourth region R4.

That is, a second surface of the second insulating layer 112 may be divided into a region on which the bridge substrate 200 is disposed and a region other than the region. For example, the second surface of the second insulating layer 112 may be divided into a region on which the second protective layer 145 is disposed and a region other than the region on which the second protective layer 145 is disposed. In addition, the third region R3 of the second insulating layer 112 may mean a region in which the bridge substrate 200 is disposed and a region in which the second protective layer 145 is not disposed. Also, the fourth region R4 of the second insulating layer 112 may refer to a region in which the bridge substrate 200 is not disposed or a region in which the second protective layer 145 is disposed. Meanwhile, the second protective layer 145 includes an opening (not shown) that is vertically overlapped with a second surface of the fourth circuit pattern 124 disposed on a second surface (To be clear, a second surface of the second-second insulating layer 112-2) of the second insulating layer 112. Accordingly, the fourth region R4 of the second insulating layer 112 may include a fourth-first region R4-1 in which the second protective layer 145 is disposed and a fourth-second region R4-2 corresponding to the opening of the second protective layer 145.

The circuit board of the embodiment includes a circuit pattern disposed on surface of each insulating layer.

For example, the embodiment includes a first circuit pattern 121, a second circuit pattern 122, a third circuit pattern 123, and a fourth circuit pattern 124.

In this case, the circuit board of the embodiment forms a circuit pattern by applying the ETS method, and accordingly, the circuit pattern disposed on an outermost side of the circuit board may have an ETS (Embedded Trace Substrate) structure. For example, a circuit pattern disposed on an uppermost side of the circuit patterns included in the circuit board may have a structure buried in the insulating layer, and a circuit pattern disposed on an second outermost side opposite to a first outermost side may have a structure protruding above the surface of the insulating layer.

The first circuit pattern 121 may be disposed on a first surface of the first insulating layer 111. For example, the first circuit pattern 121 may be disposed on an upper surface of the first insulating layer 111.

The first circuit pattern 121 is a circuit pattern disposed on an uppermost side of the circuit board. The first circuit pattern 121 is a circuit pattern disposed in a region on which a chip is to be mounted. The first circuit pattern 121 may have an ETS structure. For example, an upper surface of the first circuit pattern 121 may not be higher than an upper surface of the first insulating layer 111. For example, the upper surface of the first circuit pattern 121 may be positioned on the same plane as the upper surface of the first insulating layer 111 or may be positioned lower than the upper surface of the first insulating layer 111. For example, side surfaces and lower surfaces of the first circuit pattern 121 may be covered by the first insulating layer 111. However, a part of the lower surface of the first circuit pattern 121 may vertically overlap with a first cavity C1 to be described later. For example, a part of the lower surface of the first circuit pattern 121 may be positioned in the first cavity C1.

The first circuit pattern 121 includes a mounting pad on which a chip is to be mounted. In addition, the first circuit pattern 121 is a pattern manufactured through the ETS method, and thus may be embedded in the first surface or the upper surface of the first insulating layer 111 while having an ETS structure. Such an ETS structure has a structure in which a circuit pattern is embedded in an insulating layer, and this makes it possible to refine the circuit pattern compared to the comparative example in which the circuit pattern of the structure protruding on the insulating layer is manufactured. Accordingly, it is possible to miniaturize the mounting pad or trace in the region where the chip is mounted, and thus, it is possible to easily mount the first chip and the second chip.

The second circuit pattern 122 may be disposed on a second surface (e.g., a lower surface) of the first insulating layer 111. For example, the second circuit pattern 122 may be disposed between a second surface (e.g., a lower surface) of the first insulating layer 111 and a first surface (e.g., an upper surface) of the second-first insulating layer 112-1. The second circuit pattern 122 may protrude downward from a second surface or a lower surface of the first insulating layer 111. In addition, side and lower surfaces of the second circuit pattern 122 may be covered by the second-first insulating layer 112-1.

The third circuit pattern 123 may be disposed on a second surface of the second-first insulating layer 112-1. For example, the third circuit pattern 123 may be disposed between a second surface of the second-first insulating layer 112-1 and a first surface of the second-second insulating layer 112-2. The third circuit pattern 123 may protrude downward from a second surface or a lower surface of the second-first insulating layer 112-1. In addition, side surfaces and lower surfaces of the third circuit pattern 123 may be covered by the second-second insulating layer 112-2. Here, being covered may mean that at least a part of the side surface and/or the lower surface of the third circuit pattern 123 is covered, and may mean that the side surface and/or the lower surface are entirely covered.

The fourth circuit pattern 124 may be disposed on the second surface of the second-second insulating layer 112-2. The fourth circuit pattern 124 may be a second outermost circuit pattern among the circuit pattern 121. For example, the fourth circuit pattern 124 may be a circuit pattern disposed on a lowermost side of the circuit board. The fourth circuit pattern 124 may include a pad. The pad of the fourth circuit pattern 124 may be a terminal pad that is later connected to a main board (not shown) of an electronic device.

The first circuit pattern 121, the second circuit pattern 122, the third circuit pattern 123, and the fourth circuit pattern 124 may be formed of at least one metal material selected from gold (Au), silver (Ag), platinum (Pt), titanium (Ti), tin (Sn), copper (Cu), and zinc (Zn). In addition, the first circuit pattern 121, the second circuit pattern 122, the third circuit pattern 123, and the fourth circuit pattern 124 may be formed of a paste or solder paste including at least one metal material selected from gold (Au), silver (Ag), platinum (Pt), titanium (Ti), tin (Sn), copper (Cu), and zinc (Zn) having excellent bonding power. Preferably, the first circuit pattern 121, the second circuit pattern 122, the third circuit pattern 123, and the fourth circuit pattern 124 may be formed of copper (Cu) having high electrical conductivity and a relatively inexpensive price.

The first circuit pattern 121, the second circuit pattern 122, the third circuit pattern 123, and the fourth circuit pattern 124 may have different thicknesses. For example, a part of the first circuit pattern 121, the second circuit pattern 122, the third circuit pattern 123, and the fourth circuit pattern 124 is disposed on the first insulating layer 111 made of prepreg, and the remaining part is disposed on the second insulating layer 112 made of RCC. Accordingly, a thickness of a circuit pattern disposed on the first insulating layer 111 may be different from a thickness of a circuit pattern disposed on the second insulating layer 112. For example, a thickness of the circuit pattern 121 disposed on the first insulating layer 111 may be greater than a thickness of the circuit pattern disposed on the second insulating layer 112.

The first circuit pattern 121 and the second circuit pattern 122 may have a range of 10 μm to 25 μm. For example, the first circuit pattern 121 and the second circuit pattern 122 may have a range of 12 μm to 22 μm. For example, the first circuit pattern 121 and the second circuit pattern 122 may have a range of 13 μm to 18 μm.

When the thickness of the first circuit pattern 121 and the second circuit pattern 122 is less than 10 μm, a resistance of the first circuit pattern 121 and the second circuit pattern 122 may increase. Also, it may be difficult to form a circuit pattern having a thickness of less than 10 μm on the insulating layer including the prepreg. When the thickness of the first circuit pattern 121 and the second circuit pattern 122 exceeds 25 μm, a line width or an interval of the first circuit pattern 121 and the second circuit pattern 122 may increase, thereby increasing an overall volume of the circuit board.

The third circuit pattern 123 and the fourth circuit pattern 124 may have a range of 7 μm to 20 μm. For example, the third circuit pattern 123 and the fourth circuit pattern 124 may have a range of 8 μm to 17 μm. For example, the third circuit pattern 123 and the fourth circuit pattern 124 may have a range of 8 μm to 15 μm.

The first circuit pattern 121, the second circuit pattern 122, the third circuit pattern 123, and the fourth circuit pattern 124 may each include a pad and a trace.

The pad may include a mounting pad on which a chip is mounted, a via pad connected to a via, and a core pad or a BGA pad on which an adhesive ball (described later) connected to the main board of the electronic device is disposed. In addition, the trace may refer to a wiring in the form of a long line that transmits an electrical signal while being connected to the pad.

A pad of each of the first circuit pattern 121, the second circuit pattern 122, the third circuit pattern 123, and the fourth circuit pattern 124 may have a width in a range of 20 μm to 50 μm. A pad of each of the first circuit pattern 120 may have a width in a range of 22 μm to 40 μm. A pad of each of the first circuit pattern 120 may have a width in a range of 25 μm to 35 μm.

A trace of each of the first circuit pattern 121, the second circuit pattern 122, the third circuit pattern 123, and the fourth circuit pattern 124 may have a specific line width and a specific interval.

For example, a line width of the trace of each of the first circuit pattern 121, the second circuit pattern 122, the third circuit pattern 123, and the fourth circuit pattern 124 may be in a range of 5 μm to 20 μm. For example, a line width of the trace of each of the first circuit pattern 121, the second circuit pattern 122, the third circuit pattern 123, and the fourth circuit pattern 124 may be in the range of 7 μm to 15 μm. For example, a line width of each of the first circuit pattern 121, the second circuit pattern 122, the third circuit pattern 123, and the fourth circuit pattern 124 may be in a range of 8 μm to 12 μm.

In addition, an interval between traces of each of the first circuit pattern 121, the second circuit pattern 122, the third circuit pattern 123, and the fourth circuit pattern 124 may be in a range of 5 μm to 20 μm. For example, an interval between the traces of each of the first circuit pattern 121, the second circuit pattern 122, the third circuit pattern 123, and the fourth circuit pattern 124 may be in the range of 7 μm to 15 μm. For example, an interval between the traces of each of the first circuit pattern 121, the second circuit pattern 122, the third circuit pattern 123, and the fourth circuit pattern 124 may be in the range of 8 μm to 12 μm.

Meanwhile, each trace of the first circuit pattern 121, the second circuit pattern 122, the third circuit pattern 123, and the fourth circuit pattern 124 may have different line widths and intervals within the above range. For example, the first circuit pattern 121 is disposed in a region on which a chip is to be mounted, and thus should be configured as a fine pattern. In addition, the fourth circuit pattern 124 should be connected to the main board of the electronic device. Accordingly, the fourth circuit pattern 124 should correspond to a standard of wires included in the main board. Accordingly, a trace of the first circuit pattern 121 in an embodiment may have a smallest line width and interval among the circuit patterns, and may have the largest line width and interval of the fourth circuit pattern 124. In addition, the traces of the second circuit pattern 122 may be greater than a line width and an interval of the traces of the first circuit pattern 121 and smaller than a line width and an interval of the traces of the fourth circuit pattern 124. In addition, the traces of the third circuit pattern 123 may be greater than a line width and an interval of the traces of the second circuit pattern 122, but may be smaller than a line width and an interval of the traces of the fourth circuit pattern 124.

Also, corresponding to this, the pad of the first circuit pattern 121 may have the smallest width, and the pad of the fourth circuit pattern 124 may have the largest width among the circuit patterns. In addition, the pad of the second circuit pattern 122 may have a width greater than a width of the pad of the first circuit pattern 121 and smaller than a width of the pad of the fourth circuit pattern 124. In addition, the pad of the third circuit pattern 123 may have a width greater than a width of the pad of the second circuit pattern 122 and smaller than a width of the pad of the fourth circuit pattern 124.

Meanwhile, vias may be formed in each of the first insulating layer 111, the second-first insulating layer 112-1, and the second-second insulating layer 112-2. The via may electrically connect circuit patterns disposed on a surface of each insulating layer to each other.

A first via 131 may be formed in the first insulating layer 111. A second via 132 may be formed in each of the second-first insulating layer 112-1. In addition, a third via 133 may be formed in the second-second insulating layer 112-2. The first via 131, the second via 132, and the third via 133 may be formed to pass through only one insulating layer among the first insulating layer 111, the second-first insulating layer 112-1, and the second-second insulating layer 112-2, may be formed to pass through at least two insulating layers in common.

The first via 131 may connect between a second surface of the first circuit pattern 121 and a first surface of the second circuit pattern 122. For example, a first surface or an upper surface of the first via 131 may be connected to a lower surface of the first circuit pattern 121, and a second surface or a lower surface of the first via 131 may be connected to an upper surface of the second circuit 122.

The second via 132 may connect between a second surface of the second circuit pattern 122 and a first surface of the third circuit pattern 123. For example, a first surface or an upper surface of the second via 132 may be connected to a lower surface of the second circuit pattern 122, and a second surface or a lower surface of the second via 132 may be connected to an upper surface of the third pattern 123.

The third via 133 may connect between a second surface of the third circuit pattern 123 and a first surface of the fourth circuit pattern 124. For example, a first surface or an upper surface of the third via 133 may be connected to a lower surface of the third circuit pattern 123, and a second surface or a lower surface of the third via 133 may be connected to an upper surface of the fourth pattern 124.

The first via 131, the second via 132, and the third via 133 may have the same shape. For example, the first via 131, the second via 132, and the third via 133 may have a trapezoidal shape in which a width of a first surface is smaller than a width of a second surface. For example, a width of an upper surface of each of the first via 131, the second via 132, and the third via 133 may be smaller than a width of a lower surface of each of the first via 131, the second via 132, and the third via 133.

A width of each of the first via 131, the second via 132, and the third via 133 may satisfy a range of 12 μm to 40 μm. A width of each of the first via 131, the second via 132, and the third via 133 may satisfy a range of 15 μm to 35 μm. A width of each of the first via 131, the second via 132, and the third via 133 may satisfy a range of 18 μm to 30 μm. In addition, the width of each of the first via 131, the second via 132, and the third via 133 may mean the width of the second surface having a wider width among the first surface and the second surface of each via.

The first via 131, the second via 132, and the third via 133 may have different widths within the above range. That is, a difference between the widths of the first via 131, the second via 132 and the third via 133 may correspond to a difference in pad widths of the first circuit pattern 121, the second circuit pattern 122, the third circuit pattern 123, and the fourth circuit pattern 124.

For example, the width of the first via 131 may be the smallest among the vias. Also, the third via 133 may have the largest width among the vias. In addition, the second via 132 may be greater than the width of the first via 131 and smaller than the width of the third via 133.

The first via 131, the second via 132, and the third via 133 may be formed by filling a via hole passing through the insulating layer 110 with a conductive material.

The via hole may be formed by any one of mechanical, laser, and chemical processing. When the through hole is formed by machining, methods such as milling, drilling, and routing may be used, and when formed by laser processing, a UV or CO2 laser method may be used. In addition, when formed by chemical processing, a chemical containing aminosilane, ketones, or the like may be used. Accordingly, at least one of plurality of insulating layers may be opened.

Meanwhile, the laser processing is a cutting method that concentrates optical energy on a surface to melt and evaporate a part of the material to take a desired shape, accordingly, complex formations by computer programs can be easily processed, and even composite materials that are difficult to cut by other methods can be processed.

In addition, the laser processing has a cutting diameter of at least 0.005 mm, and has a wide range of possible thicknesses.

As the laser processing drill, it is preferable to use a YAG (Yttrium Aluminum Garnet) laser, a CO2 laser, or an ultraviolet (UV) laser. YAG laser is a laser that can process both copper foil layers and insulating layers, and CO2 laser is a laser that can process only insulating layers.

When the via hole is formed, each via may be formed by filling the inside of the via hole with a conductive material. The metal material forming the vias may be any one material selected from copper (Cu), silver (Ag), tin (Sn), gold (Au), nickel (Ni), and palladium (Pd), and the conductive material filling may use any one or a combination of electroless plating, electrolytic plating, screen printing, sputtering, evaporation, inkjetting and dispensing.

The circuit patterns and vias may have a plurality of layer structures. However, the first circuit pattern 121 in an embodiment has an ETS structure, and thus may have a layer structure different from that of other circuit patterns.

For example, the first circuit pattern 121 may have a layer structure different from that of the second circuit pattern 122, the third circuit pattern 123, and the fourth circuit pattern 124. For example, a number of layers of the first circuit pattern 121 may be different from a number of layers of the second circuit pattern 122, the third circuit pattern 123, and the fourth circuit pattern 124. For example, the number of layers of the first circuit pattern 121 may be smaller than the number of layers of the second circuit pattern 122, the third circuit pattern 123, and the fourth circuit pattern 124.

For example, the first circuit pattern 121 may include only an electrolytic plating layer.

Alternatively, the second circuit pattern 122 may include a seed layer 122-1 and an electrolytic plating layer 122-2. Also, the third circuit pattern 123 may include a seed layer 123-1 and an electrolytic plating layer 123-2. Also, the fourth circuit pattern 124 may include a seed layer 124-1 and an electrolytic plating layer 124-2.

That is, the first circuit pattern 121 is a pattern formed first among the circuit patterns of the circuit board, and accordingly, a seed layer of the first circuit pattern 121 may be removed in a final process.

Meanwhile, the first via 131 may include a seed layer 131-1 and an electrolytic plating layer 131-2 to correspond to the second circuit pattern 122. The second via 132 may include a seed layer 132-1 and an electrolytic plating layer 132-2 to correspond to the third circuit pattern 123. The third via 133 may include a seed layer 133-1 and an electrolytic plating layer 133-2 to correspond to the fourth circuit pattern 124.

An embodiment includes a protective layer. That is, the circuit board includes the first protective layer 140 disposed on a first surface or an upper surface of the first insulating layer 111. As described above, the first protective layer 140 may be disposed in the second region R2 of the first insulating layer 111. For example, the first protective layer 140 may be disposed on the second-first region R2-1 while including an opening that vertically overlaps with the second-second region R2-2, which is a region in which a through electrode (to be described later), which will be described later, is disposed among the second region R2.

In addition, the circuit board includes a second protective layer 145 disposed on a second surface or a lower surface of the second-second insulating layer 112-2. As described above, the second protective layer 145 may be disposed in the fourth region R4 of a second surface of the second-second insulating layer 112-2.

For example, the second protective layer 145 may be disposed on the fourth-first region R4-1 while including an opening that vertically overlaps with the fourth-second region R4-2 in which a conductive coupling part to be connected to the main board of the electronic device to be described later will be disposed.

Meanwhile, an embodiment provides a chip mounting region in which a plurality of first and second chips of different types can be mounted on one circuit board. In this case, the first and second chips may be first and second processor chips in which an application processor integrated into one chip of the comparative example is separated according to functions.

For example, the first-first region R1-1 of the embodiment is a region in which the first processor chip is mounted, and the first-second region R1-2 may be a region in which a second processor chip different from the first processor chip is mounted. For example, the first processor chip may be any one of an application processor (AP) chip such as a central processor (e.g., CPU), a graphic processor (e.g., GPU), a digital signal processor, an encryption processor, a microprocessor, and a microcontroller. The second processor chip may be a different type of processor chip from the first processor chip among application processor (AP) chips such as a central processor (e.g., CPU), a graphic processor (e.g., GPU), a digital signal processor, an encryption processor, a microprocessor, and a microcontroller. For example, the first processor chip may be a central processor chip, and the second processor chip may be a graphics processor chip. That is, the circuit board of the embodiment may be a circuit board for die split in which an application processor is separated by function and a separate processor chip is mounted on one substrate for each of the separated functions.

In this case, the die split structure as described above requires a connection between the first processor chip and the second processor chip. That is, the first circuit pattern 121 requires a chip trace for connecting the first processor chip and the second processor chip. In this case, the chip trace is required to be miniaturized in order to connect the first processor chip and the second processor chip within a limited space. For example, the chip trace is required to have a line width of 4 μm or less and an interval of 4 μm or less.

Meanwhile, recently, the functions required by the application processor are increasing, and accordingly, there is a demand for a circuit board capable of separately configuring the processor chips for each function and mounting the processor chips. At this time, even when the application processor is divided into two processor chips for each function, the number of terminals (Input/Output) provided in each processor chip is increasing. At this time, unlike the case where one application processor chip processes all functions as in the comparative example, when the processor chips are divided into at least two, each of the processor chips must be electrically connected to each other in order to exchange signals with each other.

In this case, when an interval between the processor chips is large, a fine pattern as in the embodiment may not be required. However, when an interval between the processor chips is large, a communication speed for exchanging signals with each other may decrease. In addition, when an interval between the processor chips is large, power consumption required for communication increases. In addition, when an interval between the processor chips is large, a length of the traces connecting between the processor chips also increases, and accordingly, there is a problem in that the signal transmission loss increases due to the vulnerability to noise.

That is, an interval between the processor chips should be 150 μm or less for reliability. For example, an interval between the processor chips should be 120 μm or less for reliability. For example, an interval between the processor chips should be 100 μm or less for reliability.

Accordingly, as described above, miniaturization of a circuit pattern having a specific line width and a specific interval or less is required in order to connect all of the wirings between the first processor chip and the second processor chip within the limited space as described above.

In addition, there are X connection wires between a conventional first processor chip and the second processor chip. In addition, when the number of connecting wires is ‘X’, the level of miniaturization of the circuit pattern in the limited space as described above may be different from that of the embodiment.

On the other hand, the number of terminals in the first processor chip and the second processor chip is gradually increasing due to reasons such as recent 5G, Internet of Things (IoT), increase in image quality increase, and increase in communication speed. Accordingly, in recent years, the connection wiring between the first processor chip and the second processor chip may be double or more (‘2×’) or three times or more (‘3×’) or ten times or more (‘10×’) of the conventional one.

However, there is a limit to the miniaturization of a line width and an interval of the traces of the circuit pattern formed in the first insulating layer 111 and the second insulating layer 112 as described above. Accordingly, a bridge substrate 200 in the embodiment is used to connect the first processor chip and the second processor chip.

To this end, the circuit board according to the embodiment includes the first cavity C1. In addition, the bridge substrate 200 may be inserted into the first cavity C1.

In this case, the first cavity C1 into which the bridge substrate 200 is to be inserted may vertically overlap with a lower surface of a pattern disposed in the first region R1 of the first circuit patterns 121. Before describing the bridge substrate 200, the first circuit pattern 121 disposed on a first surface or an upper surface of the first insulating layer 111 will be described in more detail.

The first circuit pattern 121 includes a plurality of pads.

The first circuit pattern 121 includes a first pad 121-1 disposed in a first-first region R1-1 in which the first processor chip is to be mounted.

The first pad 121-1 includes a first-first pad 121-11 disposed in a first-first sub region R1-11 and a first-second pad 121-12 disposed in a first-second sub region R1-12. In addition, the first-second first pads 121-12 are disposed in a region overlapping the first cavity C1 in a thickness direction. Accordingly, a lower surface of the first-second pad 121-12 may overlap the first cavity C1 in a vertical direction. For example, at least a part of a lower surface of the first-second pad 121-12 may be positioned in the first cavity C1. An upper surface of the first-second pad 121-12 may be a part on which the first processor chip is mounted, and a lower surface of the first-second pad 121-12 may be a part on which the bridge substrate 200 is attached.

In addition, the first circuit pattern 121 includes a second pad 121-2 disposed in a first-second region R1-2 in which the second processor chip is to be mounted.

The second pad 121-2 includes a second-first pad 121-21 disposed in a second-first sub region R1-21 and a second-second pad 121-22 disposed in a second-second sub region R1-22. In addition, the second-second pads 121-122 are disposed in a region overlapping the first cavity C1 in a thickness direction. Accordingly, a lower surface of the second-second pad 121-22 may overlap the first cavity C1 in a vertical direction. For example, at least a part of a lower surface of the second-second pad 121-22 may be disposed in the first cavity C1. An upper surface of the second-second pad 121-22 is a part on which a second processor chip is mounted, and a lower surface of the second-second pad 121-22 may be a part to which the bridge substrate 200 is attached.

The first-second pad 121-12 and the second-second pad 121-22 may be connection pads of the first pad 121-1 and the second pad 121-2 to be interconnected.

The first circuit pattern 121 further includes a third pad 121-3 on which a through electrode 150 is disposed. The third pad 121-3 may be disposed in a second-second region R2-2 of the first insulating layer 111. That is, the third pad 121-3 may overlap the opening of the first protective layer 140 in a vertical direction. For example, the third pad 121-3 may be positioned on the opening of the first protective layer 140.

Also, the first circuit pattern 121 may include a trace 121-4. The trace 121-4 may connect between the pads of the first circuit pattern 121.

Meanwhile, the first-second pad 121-12 and the second-second pad 121-22 should be connected to each other in order to arrange the first processor chip and the second processor chip on one circuit board of an embodiment. In this case, the embodiment uses the bridge substrate 200 in order to connect between the first-second pad 121-12 and the second-second pad 121-22 with high electrical reliability using the trace of the first circuit pattern 121. Accordingly, in an embodiment, the first-second pad 121-12 to be connected to the second processor chip among the first pads 121-1 is adjacent to the second pad 121-2. can be placed. Furthermore, in an embodiment, the second pad 121-22 to be connected to the first processor chip among the second pads 121-2 may be disposed adjacent to the first pad 121-1. Accordingly, the first-second pad 121-12 and the second-second pad 121-22 of the embodiment may be disposed adjacent to each other.

Meanwhile, a through electrode 150 may be disposed on a third pad 121-3 to have a predetermined height. In the comparative example, the first package and the second package were connected using the second adhesive ball 13. However, it is difficult to match the pitch between the first semiconductor package and the second semiconductor package due to the pitch limit of the second adhesive balls 13. Therefore, the second substrate 15 in the comparative example was additionally required. In contrast, the through electrode 150 in the embodiment is used to connect the first semiconductor package and the second semiconductor package. In this case, the through electrode 150 has higher electrical and thermal conductivity than the second adhesive ball 13. For example, the through electrode 150 in the embodiment is formed of a metal wire (wire). For example, the metal wire may be a copper wire. Accordingly, in the embodiment, an interval between a plurality of through electrodes may be minimized by connecting the plurality of semiconductor packages using the through electrode 150 formed of the metal wire. Furthermore, the embodiment may improve heat transfer characteristics between the first semiconductor package and the second semiconductor package by using the through electrode 150 formed of a metal wire, and thus, heat dissipation characteristics may be improved.

In an embodiment, a wire bonding process may be performed on the third pad 121-3 to form the through electrode 150 having a predetermined height. Accordingly, the through electrode 150 may be referred to as a wire part.

In this case, the through electrode 150 may be divided into a plurality of parts.

For example, the through electrode 150 may include a first conductive coupling part 150-1, a reinforcing part 150-2, and a through part 150-3. At this time, the first conductive coupling part 150-1, the reinforcing part 150-2, and the through-electrode 150 are only for dividing the through-electrode 150 by regions, and this be a single component substantially integrally formed. That is, the through electrode including the first conductive coupling part 150-1, the reinforcing part 150-2, and the through part 150-3 of an embodiment may be formed on the third pad 121-3 by bonding a metal wire.

The through part 150-3 may be disposed on the first insulating layer 111 and the first protective layer 160, and may pass through the second molding layer 160. The through part 150-3 may correspond to a wire used to form the through electrode 150. For example, the through part 150-3 may have a first width W1. The first width W1 may correspond to a width of a wire (specifically, a diameter of a wire) used to form the through electrode 150. The first width W1 of the through part 150-3 may be in a range of 10 μm to 100 μm. The first width W1 of the through part 150-3 may be in a range of 12 μm to 98 μm. The first width W1 may have a range of 15 μm to 95 μm. When the first width W1 of the through part 150-3 is less than 10 μm, a straightness of the through part 150-3 may decrease in a process of forming the through electrode 150 on the third pad 121-3. The straightness may mean an inclination angle of the through part 150-3 with respect to a virtual vertical line perpendicular to an upper surface of the first insulating layer 111. For example, the straightness may decrease as the angle of inclination of the through part 150-3 with respect to the virtual vertical line increases, and, the straightness may increase as the inclination angle decreases. When the first width W1 of the through part 150-3 exceeds 100 μm, an interval between a plurality of through electrodes increases, and accordingly, a pitch of the through electrodes may increase. Meanwhile, the first width W1 of the through part 150-3 may be determined by a height H1 of the through electrode 150. For example, a straightness of the through part 150-3 may decrease as the height H1 of the through electrode 150 increases. Accordingly, in the embodiment, the first width W1 of the through part 150-3 increases as the height H1 of the through electrode 150 increases. For example, a height H1 of the through electrode 150 in the embodiment may be determined by a height of the chip mounted on the circuit board of the embodiment. For example, a height H1 of the through electrode 150 may be in a range of 50 μm to 200 μm. And, in the embodiment, when the height H1 of the through electrode 150 exceeds 100 μm, the first width W1 of the through part 150-3 is set to have a minimum of 40 μm or more. In addition, when the height H1 of the through electrode 150 is less than 100 μm, the first width W1 of the through part 150-3 may satisfy a range of 10 μm to 100 μm. In addition, when the height H1 of the through electrode 150 exceeds 100 μm, the first width W1 of the through part 150-3 may satisfy a range of 40 μm to 100 μm.

Meanwhile, the through electrode 150 may include a first conductive coupling part 150-1 between the third pad 121-3 and the through electrode 150.

The first conductive coupling part 150-1 may be a body part formed in the process of bonding a wire on the third pad 121-3. The first conductive coupling part 150-1 may be formed on the third pad 121-3 to have a second height H2 and a third width W3.

For example, the first conductive coupling part 150-1 may be a part in which the metal wire is bundled as bonding is performed while the metal wire is pressed when bonding a metal wire for forming the through electrode 150 on the third pad 121-3. The first conductive coupling part 150-1 may be referred to as a wire ball. The first conductive coupling part 150-1 may have a third width W3. The third width W3 of the first conductive coupling part 150-1 may satisfy a range of 150% to 300% of the first width W1 of the through part 150-3. For example, the third width W3 of the first conductive coupling part 150-1 may satisfy a range of 160% to 250% of a first width W1 of the through part 150-3. For example, the third width W3 of the first conductive coupling part 150-1 may satisfy a range of 180% to 240% of the first width W1 of the through part 150-3. When the third width W3 of the first conductive coupling part 150-1 is less than 150% of the first width W1 of the through part 150-3, there may be a problem that the through part 150-3 is not stably supported by the first conductive coupling part 150-1, and accordingly, the straightness of the through part 150-3 may decrease. In addition, when the third width W3 of the first conductive coupling part 150-1 is less than 150% of the first width W1 of the through part 150-3, a bonding area between the third pad 121-3 and the through electrode 150 is reduced, and accordingly, an electrical reliability problem (e.g., an increase in signal loss as electrical resistance increases) and a physical reliability problem (e.g., a film removal problem in which the through electrode is separated from the third pad) may occur. In addition, when the third width W3 of the first conductive coupling part 150-1 exceeds 300% of the first width W1 of the through part 150-3, an interval between the plurality of through electrodes increases, and accordingly, it may be difficult to integrate the circuit board.

Meanwhile, the through electrode 150 in the embodiment may include, a reinforcing part 150-2 formed between the first conductive coupling part 150-1 and the through part 150-3. The reinforcing part 150-2 is formed between the first conductive coupling part 150-1 and the through part 150-3, and may be referred to as a support part for supporting the through part 150-3. The reinforcing part 150-2 may have a second width W2 greater than the first width W1 of the through part 150-3. For example, the reinforcing part 150-2 may have a second width W2 in the range of 105% to 160% of the first width W1 of the through part 150-3. For example, the reinforcing part 150-2 may have a second width W2 in the range of 108% to 155% of the first width W1 of the through part 150-3. For example, the reinforcing part 150-2 may have a range of 110% to 150% of the first width W1 of the through part 150-3. When the second width W2 of the reinforcing part 150-2 is 105% or less of the first width W1 of the through part 150-3, a problem may occur that the through part 150-3 is not stably supported by the reinforcing part 150-2, and accordingly, the straightness of the through part 150-3 may decrease. In addition, when the second width W2 of the reinforcing part 150-2 exceeds 160% of the first width W1 of the through part 150-3, a process time for forming the reinforcing part 150-2 may increase, and thus process complexity may increase.

Meanwhile, the embodiment may be formed to have a width greater than a width of the metal wire (i.e., a first width of the through part) by applying pressure to the metal wire in a direction toward the first conductive coupling part 150-1 in a state in which the first conductive coupling part 150-1 is formed (for example, by pressing a metal wire in a downward direction).

In this case, an upper surface of the first conductive coupling part 150-1 may include a concave part 150-1a formed in a process of forming the reinforcing part 150-2. In addition, the reinforcing part 150-2 may be formed to have a predetermined height H3 in the concave part 150-1a of the first conductive coupling part 150-1.

In an embodiment, the through electrode 150 may be referred to as a wire part formed by bonding a metal wire, and includes a through part 150-3 having a width corresponding to a diameter of the metal wire. Accordingly, the width of the through electrode 150 in the embodiment may be reduced compared to the comparative example. Accordingly, when the through electrode 150 of the embodiment includes a first through electrode 151 and a second through electrode 152, a distance D1 between the first through electrode 151 and the second through electrode 152 may be reduced compared to the comparative example. Furthermore, a metal post in a related art is used to solve the problem of the solder ball of the comparative example of FIG. 1. However, the metal post has a problem in that the manufacturing process is complicated as the seed layer formation and plating process are performed, and further, the manufacturing cost increases compared to this embodiment. Furthermore, a width of the metal post in the conventional structure including the metal post is at least 110 μm, and thus an interval between the plurality of metal posts is increased compared to the present embodiment, accordingly, there is a problem in that the width of the circuit board in a horizontal direction increases, so that the degree of circuit integration decreases. Furthermore, a conventional structure including a metal post has a problem in that it requires a technique such as to manage a plating solution, a plating facility, and a plating condition by a chemical method during a plating process.

On the other hand, the through electrode 150 including the first conductive coupling part 150-1, the reinforcing part 150-2 and the through electrode 150 may be formed by simply bonding a metal wire on the third pad 121-3. Accordingly, the embodiment can simplify the process for forming the through electrode 150, furthermore, the manufacturing cost can be reduced. Furthermore, the through electrode 150 has a width corresponding to the diameter of the metal wire, which is smaller than a metal post formed by a plating process. Accordingly, the embodiment may reduce an interval between the plurality of through electrodes, thereby reducing a width of the circuit board in a horizontal direction, and furthermore, it is possible to improve the circuit integration of the circuit board.

Meanwhile, in the embodiment, a pitch between a first through electrode 151 and a second through electrode 152 adjacent to each other may be 40 μm to 100 μm. For example, a pitch between the first through electrode 151 and the second through electrode 152 adjacent to each other may be 40 μm to 100 μm. For example, a pitch between the first through electrode 151 and the second through electrode 152 adjacent to each other may be 40 μm to 100 μm. The pitch may mean a distance from a center of the first through electrode 151 to a center of the second through electrode 152. In this case, in the case of a structure of the prior art including a solder ball or a copper post, a width of the solder ball or the copper post is 110 μm or more, and thus the pitch has at least 120 μm or more. In contrast, in the embodiment, the first through electrode 151 and the second through electrode 152 have a width corresponding to a diameter of the metal wire, and accordingly, a pitch between the first through electrode 151 and the second through electrode 152 may be reduced to 100 μm or less.

Meanwhile, a straightness of the through electrode 150 in an embodiment may be 10 degrees or less. Preferably, a straightness of the through electrode 150 may be 8 degrees or less. More preferably, a straightness of the through electrode 150 may be 5 degrees or less. As described above, the straightness of the through electrode 150 may mean an inclination angle of the through part 150-3 of the through electrode 150 with respect to a virtual vertical line perpendicular to an upper surface of the first insulating layer 111. And, the closer the inclination angle to 0 degree, the higher the straightness.

Meanwhile, as described above, a first cavity C1 is formed in the insulating layer 110 in the embodiment, and the bridge substrate 200 may be inserted and/or buried in the formed first cavity C1.

To this end, a first cavity C1 is formed in the insulating layer 110.

The first cavity C1 includes a first part C1-1 formed in the first insulating layer 111, a second part C1-2 formed in the second-first insulating layer 112-1, and a third part C1-3 formed on the second-second insulating layer 112-2. In this case, a slope of an inner wall of the first part C1-1 may be different from a slope of an inner wall of the second part C1-2 and the third part C1-3. For example, the slope of the inner wall of the first part C1-1 may be greater than the slope of the inner wall of the second part C1-2 and the third part C1-3. That is, the first part C1-1 is formed in the first insulating layer 111 including the prepreg, and accordingly, the slope of the inner wall of the first part C1-1 may be greater than the slope of the inner walls of the second part C1-2 and the third part C1-3 formed in the second insulating layer 112 including the RCC.

The first cavity C1 may vertically overlap with a lower surface of at least some of the first circuit patterns 121.

Specifically, the first-second pad 121-12 and the second-second pad 121-22 in the first circuit pattern 121 may overlap the first cavity C1 in a thickness direction. Accordingly, at least a part of the first-second pad 121-12 and the second-second pad 121-22 may be disposed in the first cavity C1.

Meanwhile, the first insulating layer 111 includes a first part 111-1 disposed between the first circuit pattern 121 and the second circuit pattern 122 and a second part surrounding the first circuit pattern 121. In this case, a thickness of the first insulating layer 111 means a thickness of the first part 111-1.

In this case, the first cavity C1 in an embodiment may partially open the second part 111-2 of the first insulating layer 111. Accordingly, the second part 111-2 of the first insulating layer 111 may have a different thickness for each region. For example, the second part 111-2 of the first insulating layer 111 may include a second-first part overlapping the first cavity C1 in a thickness direction and a second-second part other than the second-first part. In addition, the second-second part may have a thickness substantially equal to a thickness of the first circuit pattern 121. Alternatively, the second-first part overlapping the first cavity C1 may be smaller than the thickness of the first circuit pattern 121, further the thickness of the first-second pad 121-12 and the second-second pad 121-22. For example, the thickness T1 of the second-first part of the first insulating layer 111 overlapping the first cavity C1 may be smaller than the thickness of the first-second pad 121-12 and the second-second pad 121-22.

Here, the first cavity C1 for inserting the bridge substrate 200 in the embodiment as described above is formed in the insulating layer 110. In this case, the first cavity C1 is formed to substantially pass through the insulating layer 110. Here, the first-second pad 121-12 and the second-second pad 121-22 in the embodiment may be supported through the second-first part of the first insulating layer 111. In this case, a thickness T1 of the second-first part of the first insulating layer 111 is smaller than that of the first-second pad 121-12 and the second-second pad 121-22. Accordingly, the first-second pad 121-12 and the second-second pad 121-22 may not be stably supported as the first cavity C1 is formed. In this case, as described above, the first insulating layer 111 in the embodiment is formed of a prepreg in order to stably support the first-second pad 121-12 and the second-second pad 121-22 with a minimum thickness while improving the bending characteristics by securing the rigidity of the circuit board. Accordingly, even when the first cavity C1 in the embodiment is formed, the first-second first pad 121-12 and the second-second second pad 121-22 may be stably supported, and thus reliability can improve.

On the other hand, a third conductive coupling part 201 is disposed on lower surfaces of a first-second pad 121-12 and a second-second pad 121-22 overlapping the first cavity C1 in a vertical direction. In addition, the bridge substrate 200 may be attached to the first-second pad 121-12 and the second-second pad 121-22 in the first cavity C1 through the third conductive coupling part 201.

The bridge substrate 200 may electrically connect the first-second pad 121-12 and the second-second pad 121-22 to each other. For example, the bridge substrate 200 may electrically connect the first processor chip and the second processor chip to each other through the first-second pad 121-12 and the second-second pad 121-22. For example, the bridge substrate 200 may perform die-to-die interconnection for electrically connecting a plurality of processor chips mounted on a circuit board to each other. The plurality of processor chips should be electrically connected to each other within a limited space. In this case, a very dense connection circuit is required in a limited space in order to connect the plurality of processor chips. Accordingly, the bridge substrate 200 according to the embodiment includes a high-density circuit layer, thereby electrically connecting a plurality of processor chips mounted on the circuit board.

To this end, the bridge substrate 200 may include an ultra-miniaturized pattern.

The bridge substrate 200 includes a base layer 210, an insulating layer 220 disposed on the base layer 210, a circuit layer 230 disposed on the insulating layer 220, a via layer 240 passing through the insulating layer 220, and a pad layer 250 formed on an outermost side of the insulating layer 220. The insulating layer 220, the circuit layer 230, the via layer 240, and the pad layer 250 may be referred to as a redistribution layer of the bridge substrate 200 disposed on the base layer 210.

The base layer 210 may improve the bending characteristics of the bridge substrate 200. For example, the base layer 210 may support the bridge substrate 200. To this end, the base layer 210 may include silicon (Si), glass, ceramic, or the like.

The insulating layer 220 of the bridge substrate 200 may be disposed on one surface of the base layer 210. The insulating layer 220 may be composed of a plurality of layers. The insulating layer 220 may include polyimide (PI), but is not limited thereto. For example, the insulating layer 220 may include an organic insulating layer such as SiO2.

A circuit layer 230 and a via layer 240 are formed on the insulating layer 220 of the bridge substrate 200. The circuit layer 230 and the via layer 240 may be formed by plating a metal material in a circuit pattern groove (not shown) or a via hole (not shown) formed by exposing and developing the insulating layer 220.

Accordingly, the circuit layer 230 and the via layer 240 of the bridge substrate 200 may have a layer structure different from that of the first circuit pattern 121, the second circuit pattern 122, the third circuit pattern 123, the fourth circuit pattern 124, the first via 131, the second via 132, and the third via 133.

For example, the circuit layer 230 and the via layer 240 of the bridge substrate 200 may have a greater number of layers than the first circuit pattern 121, the second circuit pattern 122, the third circuit pattern 123, the fourth circuit pattern 124, the first via 131, the second via 132, and the third via 133.

For example, the circuit layer 230 may include a first metal layer 231 and a second metal layer 232. The first metal layer 231 may be a metal layer formed through sputtering. To this end, the first metal layer 231 may include a titanium (Ti) layer and a copper (Cu) layer formed through a sputtering process. The titanium (Ti) layer may have a thickness of 0.01 μm to 0.15 μm. For example, the titanium (Ti) layer may have a thickness of 0.03 μm to 0.12 μm. For example, the titanium (Ti) layer may have a thickness of 0.05 μm to 0.10 μm. The copper (Cu) layer may have a thickness of 0.01 μm to 0.35 μm. For example, the copper (Cu) layer may have a thickness of 0.05 μm to 0.32 μm. For example, the copper (Cu) layer may have a thickness of 0.1 μm to 0.3 μm. A thickness of the first metal layer 231 that is the sum of the thicknesses of the titanium (Ti) and copper (Cu) layers may be 0.5 μm or less.

Preferably, the thickness of the first metal layer 231 may be 0.4 μm or less. More preferably, the thickness of the first metal layer 231 may be 0.3 μm or less. When the thickness of the first metal layer 231 exceeds 0.5 μm, it may be difficult to refine the circuit layer 230. Specifically, the forming process of the circuit layer 230 includes a seed layer removing process of removing the first metal layer 231. In this case, as the thickness of the first metal layer 231 increases, the etching amount in the seed layer process increases, and accordingly, it becomes difficult to miniaturize the entire circuit layer 230.

In the embodiment, the first metal layer 231 is formed by a sputtering process, and the circuit layer 230 may be miniaturized.

The second metal layer 232 may be an electrolytic plating layer formed by electrolytic plating the first metal layer 231 as a seed layer. The second metal layer 232 may have a thickness in the range of 2 μm to 12 μm. The second metal layer 232 may have a thickness in a range of 3 μm to 11 μm. The second metal layer 232 may have a thickness in a range of 4 μm to 10 μm.

When the thickness of the second metal layer 232 is less than 2 μm, the second metal layer 232 is also etched in the seed layer etching process, so that it may be difficult to normally implement the circuit layer 230. When the thickness of the second metal layer 232 is greater than 12 μm, it may be difficult to refine the circuit layer 230.

Each of the circuit layers 230 having the above-described layer structure may have a thickness in a range of 3 μm to 13 μm. The circuit layer 230 having the above-described layer structure may have a thickness in a range of 4 μm to 12 μm. Each of the second circuit patterns 220 having the above-described layer structure may have a thickness in a range of 5 μm to 11 μm. When the thickness of the circuit layer 230 is less than 5 μm, a resistance of the circuit layer 230 may increase, thereby reducing reliability in connection with the first and second processor chips. When the thickness of the circuit layer 230 exceeds 11 μm, it may be difficult to implement a fine pattern required for the bridge substrate 200.

The circuit layer 230 may have an ultra-miniaturized pattern. For example, the circuit layer 230 may have a line width of 5 μm or less. For example, the circuit layer 230 may have a line width of 3 μm or less. For example, the circuit layer 230 may have a line width of 2 μm or less. The circuit layer 230 may have an interval of 5 μm or less. The interval may mean a spacing between traces of the circuit layer 230 disposed on the same layer. For example, the second circuit layer 230 may have an interval of 3 μm or less. For example, the circuit layer 230 may have an interval of 2 μm or less.

Preferably, the circuit layer 230 may have a line width of 1 μm to 5 μm. The line width may mean a line width of traces constituting the second circuit pattern 220. The circuit layer 230 may have a line width in a range of 1.2 μm to 3 μm. The circuit layer 230 may have a line width in a range of 1.5 μm to 2 μm. When the line width of the circuit layer 230 is less than 1 μm, the resistance of the circuit layer 230 increases, and thus, normal communication with the processor chip may be difficult. When the line width of the circuit layer 230 is greater than 5 μm, it may be difficult to implement the bridge substrate 200 for connection between a plurality of processor chips in a limited space. For example, when the line width of the circuit layer 230 is greater than 6 μm, it may be difficult to arrange the bridge substrate 200 including traces for connecting a plurality of processor chips in the first cavity C1 formed in a limited space.

Meanwhile, the via layer 140 of the bridge substrate 200 may also include a first metal layer 241 and a second metal layer 242 to correspond to the circuit layer 230.

In addition, the bridge substrate 200 includes a pad layer 250 disposed on an outermost insulating layer 222. The pad layer 250 may include a first metal layer 251 and a second metal layer 252 corresponding to the circuit layer 230 and the via layer 140.

The pad layer 250 may be a pad of the bridge substrate 200 on which the third conductive coupling part 201 is disposed. That is, the pad layer 250 may be disposed on an outermost side of the bridge substrate 200, and the third conductive coupling part 201 may be disposed on the pad layer 250. In addition, the bridge substrate 200 may be attached to the first-second pad 121-12 and the second-second pad 121-22 through the third conductive coupling part 201.

In the embodiment, it is possible to easily connect the first-second pad 121-12 and the second-second pad 121-22 within a limited space by inserting the bridge substrate 200 into the first cavity (C1) as described above,

Meanwhile, a first molding layer 170 may be formed in the first cavity C1. The first molding layer 170 may fill the first cavity C1 in a state in which the bridge substrate 200 is inserted and attached to the first cavity C1. That is, the first molding layer 170 may protect the bridge substrate 200 inserted into the first cavity C1. In this case, at least a part of the bridge substrate 200 may be exposed to a lower surface of the first molding layer 170. For example, the base layer 210 of the bridge substrate 200 may be exposed to a lower surface of the first molding layer 170. Accordingly, the heat generated by the bridge substrate 200 in the embodiment can be easily radiated to an outside, and thus the heat dissipation property of the bridge substrate 200 can be improved. Furthermore, the reliability of the bridge substrate 200 in an embodiment may be improved, and communication performance between the first processor chip and the second processor chip connected through the bridge substrate 200 may be improved. However, the embodiment is not limited thereto. For example, the bridge substrate 200 may be buried in the first molding layer 170.

In addition, although a general semiconductor package includes a bridge substrate, the bridge substrate is disposed in a state in which it is embedded in the circuit board. For example, a bridge substrate in a conventional semiconductor package is embedded in a circuit board, and thus has a structure in which an insulating layer and a circuit pattern are disposed on and below the bridge substrate. However, the bridge substrate in the case of such a structure may be bent according to bending characteristics of the circuit board, and thus reliability of the bridge substrate may be deteriorated. For example, cracks may occur in the bridge substrate due to a difference between the coefficient of thermal expansion of the circuit board and the coefficient of thermal expansion of the bridge substrate, and thus, damage to the ultra-miniaturized circuit layer included in the bridge substrate may occur.

In contrast, the bridge substrate 200 in the embodiment includes a first molding layer 170 that is included in the first cavity C1 of the circuit board and protects it. In addition, the insulating layer 110 or the circuit patterns constituting the circuit board are not disposed under the bridge substrate 200. Therefore, the embodiment can maintain reliability by improving the bending characteristics of the bridge substrate 200 in various use environments of the circuit board, and accordingly, communication performance between the first processor chip and the second processor chip may be improved.

Meanwhile, a second molding layer 160 in an embodiment may be formed on the first insulating layer 111. Preferably, the second molding layer 160 may be formed on the first protective layer 140. The first protective layer 140 is a kind of insulating layer, but is referred to as a ‘protective layer’ to distinguish it from the insulating layer 110.

The second molding layer 160 may be disposed on a second region R2 of the first insulating layer 111. The second molding layer 160 may be disposed to surround the through electrode 150. For example, the second molding layer 160 may be a protective layer for protecting the through electrode 150.

Accordingly, the through electrode 150 may pass through the second molding layer 160. For example, the through part 150-3 of the through electrode 150 may pass through the second molding layer 160.

In this case, a width of the opening of the first protective layer 160 may be greater than a width of the through electrode 150. For example, the width of the opening of the first protective layer 160 may be greater than the width of the first conductive coupling part 150-1 of the through electrode 150. Accordingly, the second molding layer 160 may be disposed in the opening of the first protective layer 160, and may be formed to surround at least a part of the first conductive coupling part 150-1 and the reinforcing part 150-2 of the through electrode 150.

The second molding layer 160 may include a second cavity C2. For example, the second molding layer 160 may include a second cavity C2 vertically overlapping with the first region R1 of the first insulating layer 111. For example, the second molding layer 160 may include a second cavity C2 that vertically overlaps with a first pad 121-1 and a second pad 121-2 of the first circuit pattern 121 disposed in the first region R1. Accordingly, an upper surfaces of the first and second pads 121-1 and 121-2 for mounting the first and second processor chips among the first circuit patterns 121 may be positioned in the second cavity C2.

Meanwhile, a metal layer 312 in an embodiment may be disposed on an upper surface of the first insulating layer 111. The metal layer 312 may be a seed layer used to form the first circuit pattern 121. Also, the metal layer 312 may be a laser stopper used to form the cavity C2. That is, in the embodiment, a part of the seed layer used to form the first circuit pattern 121 is used as a laser stopper for forming the second cavity C2.

In addition, it may be difficult to accurately match a size of the metal layer used as the laser stopper and the second cavity C2, accordingly, a part of the metal layer 312 may remain between the first insulating layer 111 and the second molding layer 160. However, the embodiment is not limited thereto, and the metal layer 312 may be completely removed through an additional etching process.

The circuit board of the embodiment includes a first insulating layer and a second insulating layer. The first insulating layer includes a prepreg, and the second insulating layer includes RCC. The embodiment minimizes the number of layers of the first insulating layer including the prepreg, and configures the circuit board by using the number of the second insulating layers including the RCC. Accordingly, the embodiment may reduce the overall thickness of the circuit board by using the second insulating layer while improving the overall warpage characteristics of the circuit board by using the first insulating layer. Accordingly, the embodiment may slim the circuit board, and further slim the semiconductor package.

In addition, the embodiment includes a first circuit pattern having an ETS structure on an upper surface of the first insulating layer. In addition, the first circuit pattern includes first and second pads on which chips are mounted. In this case, upper surfaces of the first and second pads are used as mounting pads on which the first and second chips are mounted, lower surfaces of the first pad and the second pad overlap the first cavity in a vertical direction, and thus may be used as a terminal pad on which a bridge substrate is mounted. Accordingly, the embodiment can reduce the signal transmission distance between the chip and the bridge substrate by arranging both the chip and the bridge substrate using a single pad, and accordingly, signal transmission loss can be minimized.

In addition, the embodiment allows the first circuit pattern to have an ETS structure and to be supported through a portion of the first insulating layer including the prepreg. Accordingly, a problem of physical reliability of the first pad and the second pad that may occur as the first cavity vertically overlaps with the first pad and the second pad (e.g., exposed through the first cavity) can be solved, and thereby improving product reliability.

In addition, although a general semiconductor package includes a bridge substrate, the bridge substrate is disposed in a state in which it is embedded in the circuit board. For example, a bridge substrate in a conventional semiconductor package is embedded in a circuit board, and thus has a structure in which an insulating layer and a circuit pattern are disposed on and below the circuit board.

However, the bridge substrate in the case of such a structure may be bent according to the bending characteristics of the circuit board, and thus reliability of the bridge substrate may be deteriorated. For example, a crack may occur in the bridge substrate due to a difference between the coefficient of thermal expansion of the circuit board and the coefficient of thermal expansion of the bridge substrate, and accordingly, damage to the ultrafine circuit layer included in the bridge substrate may occur. On the other hand, the bridge substrate of the embodiment may be disposed in a first cavity of the circuit board and protected by a first molding layer. Furthermore, an insulating layer or circuit patterns constituting the circuit board are not disposed under the bridge substrate. Accordingly, the embodiment may maintain reliability by improving the bending characteristics of the bridge substrate in various usage environments of the circuit board, thereby improving communication performance between a first processor chip and a second processor chip. In addition, heat generated from the bridge substrate can be easily radiated to the outside by allowing at least a portion of the bridge substrate of the embodiment to be exposed to the outside of the first molding layer, and thereby increasing heat dissipation of the bridge substrate. Furthermore, the embodiment may improve the reliability of the bridge substrate, and thereby improving the performance of signal transmission or power transmission between the first processor chip and the second processor chip connected through the bridge substrate.

In addition, the embodiment includes a second molding layer including a second cavity while protecting the through electrode on an upper side of the circuit board and a third molding layer disposed in the second cavity of the second molding layer to mold a chip. In addition, the second molding layer and the third molding layer in the embodiment have different strengths from each other. Accordingly, the through electrode and the chip in the embodiment may be stably protected by forming the second and third molding layers of different materials. In addition, damage to the circuit board in the embodiment can be protected by the manufacturing process of the circuit board in a state in which the second molding layer is formed when the bridge substrate is mounted, and further improve the reliability of the connection between the circuit board and the bridge substrate.

In addition, the through electrode in the embodiment may be a wire part formed by bonding a metal wire. To this end, the through electrode may include a first conductive coupling part, a reinforcing part, and a through part. In this case, the through electrode according to the embodiment includes a through part corresponding to the metal wire, and thus a width of the through electrode may be reduced. Accordingly, spacing and pitch between the plurality of through electrodes in the embodiment may be reduced, and further, a width of the circuit board in a horizontal direction may be reduced, and thus the degree of integration of the circuit board may be improved.

In addition, the through electrode in the embodiment includes a first conductive coupling part, thereby increasing the bonding force between the third pad and the through part, and furthermore, it is possible to reduce a signal loss caused by a difference between a width of the third pad and a width of the through part. For example, when the through part is directly disposed on the third pad, the bonding force between the third pad and the through part may decrease, so that the through part may be detached from the third pad. In addition, when the through part is disposed directly on the third pad and a signal is transmitted between the third pad and the through part, signal loss may occur due to a sudden change in a width between the third pad and the through part. In this case, the embodiment can solve the above problems by forming the first conductive coupling part between the third pad and the through part, and accordingly, electrical reliability and physical reliability of the circuit board may be improved.

In addition, the through electrode of the embodiment includes a reinforcing part disposed between the first conductive coupling part and the through part. The reinforcing part may have a predetermined height on the first conductive coupling part and may have a greater width than the through part. Accordingly, the through part of the embodiment can be stably supported through the reinforcing part, so that straightness of the through electrode can be improved, and thus electrical reliability of the through electrode can be improved.

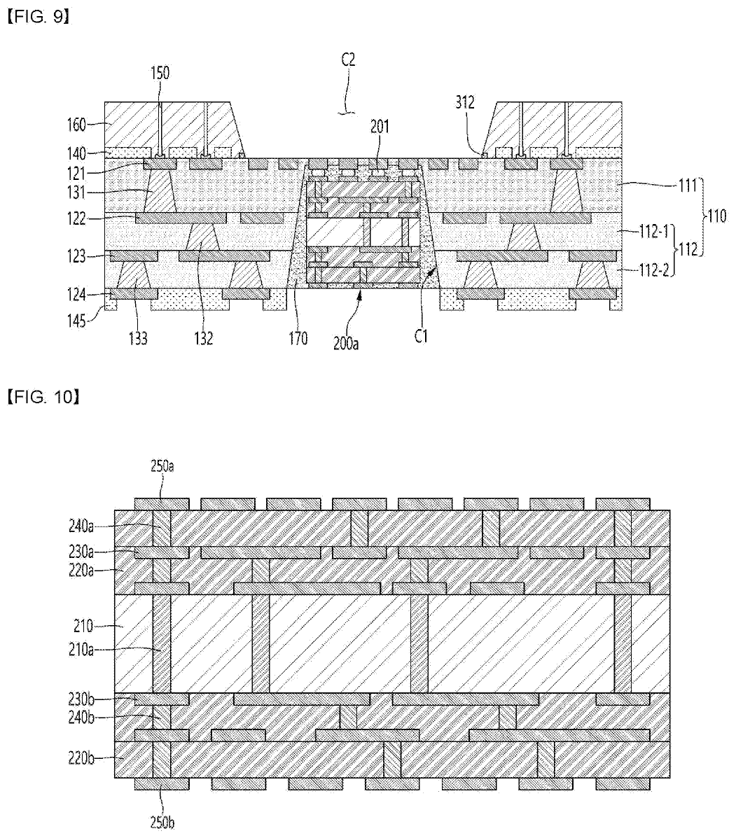

FIG. 9 is a view showing a circuit board according to a second embodiment, and FIG. 10 is a view showing a bridge substrate of FIG. 9.

Referring to FIGS. 9 and 10, the circuit board according to the second embodiment is similar to the circuit board shown in FIG. 2, and has a difference in a structure of a bridge substrate.

A circuit board according to the second embodiment includes a first insulating layer 111 and a second insulating layer 112. In addition, a first cavity C1 may be formed in the first insulating layer 111 and the second insulating layer 112.

In addition, the circuit board according to the second embodiment includes a first circuit pattern 121, a second circuit pattern 122, a third circuit pattern 123, and a fourth circuit pattern 124.

In addition, the circuit board according to the second embodiment includes a first via 131, a second via 132, and a third via 133.

In addition, the circuit board according to the second embodiment includes a first protective layer 140 and a second protective layer 145. The first protective layer 140 and the second protective layer 145 may also be referred to as insulating layers. For example, the insulating layer 110 may be referred to as a ‘first insulating layer’, the first protective layer 140 may be referred to as a ‘second insulating layer’, and the second protective layer 150 may be referred to as a ‘third insulating layer’.

In addition, the circuit board according to the second embodiment includes a through electrode 150 disposed on a third pad 121-3 of a first circuit pattern 121.

In addition, the circuit board according to the second embodiment includes a second molding layer 160 disposed on the first protective layer 140 and molding the through electrode 150. In addition, the second molding layer 160 includes a second cavity C2 that vertically overlaps with a pad disposed in a region on which a chip is to be mounted among the first circuit patterns 121.

On the other hand, the circuit board according to the second embodiment may include a bridge substrate 200a disposed in the first cavity C1 formed in the first insulating layer 111 and the second insulating layer 112 and connected to the first circuit pattern 121 through the third conductive coupling part 201.

In this case, the bridge substrate 200a included in the circuit board of the second embodiment may be different from the bridge substrate 200 included in the circuit board of the first embodiment.

For example, the bridge substrate 200 of the circuit board of the first embodiment includes is formed on only one side of the base layer 210 as the center and includes an insulating layer, a circuit layer, a via layer, and a pad layer corresponding to the redistribution layer. For example, the bridge substrate 200 included in the circuit board of the first embodiment may be a single-sided bridge substrate.

In contrast, the bridge substrate 200a of the circuit board of the second embodiment may include an insulating layer, a circuit layer, a via layer, and a pad layer corresponding to the redistribution layer may be disposed on both sides of the base layer as the center. In addition, the redistribution layers disposed on both sides may be electrically connected to each other.

Specifically, the bridge substrate 200a includes a base layer 210.

In addition, the bridge substrate 200a includes a first insulating layer 220a, a first circuit layer 230a, a first via layer 240a, and a first pad layer 250a disposed on one side of the base layer 210.

In addition, the bridge substrate 200a includes a second insulating layer 220b, a second circuit layer 230b, a second via layer 240b, and a second pad layer 250b disposed on the other side of the base layer 210.

In addition, the bridge substrate 200a includes a base via 210a passing through the base layer 210. The base via 210a may electrically connect the first circuit layer 230a disposed on one side thereof and the second circuit layer 230b disposed on the other side thereof with the base layer 210 as a center. The base via 210a may be a through silicon via (TSV).

As described above, the bridge substrate 200a of the second embodiment is implemented as a double-sided bridge substrate, and accordingly, it is possible to provide a redistribution layer connecting a greater number of the first-second pad 121-12 and the second-second pad 121-22 in a limited space.

For example, when the bridge substrate 200 having the same cross-section as in the first embodiment is used, there is a limit in reducing the pitch of the pad layers 250 of the bridge substrate 200. This is, the cross-sectional bridge substrate 200 should include a circuit layer such as a trace connecting them in addition to the pad layer 250 on the outermost side, accordingly, there is a limit in reducing the pitch between the pad layers 250.

On the other hand, the first pad layer 250a connected to the first-second pad 121-12 and the second-second pad 121-22 may be disposed on the outermost side of the double-sided bridge substrate 200a of the second embodiment, and a circuit layer such as a trace connecting them may be disposed below the base layer 210. Accordingly, the pitch of the pad layers connected to the first-second pad 121-12 and the second-second pad 121-22 can be further reduced in the case of the second embodiment. Accordingly, it is possible to easily connect high-performance processor chips within a limited space.

Hereinafter, a method of manufacturing a circuit board according to an embodiment will be described.

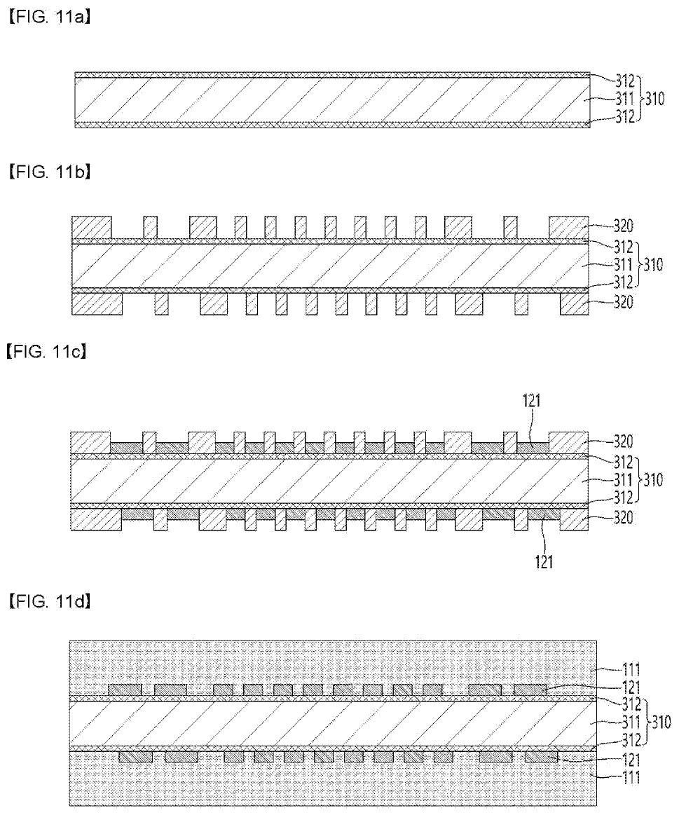

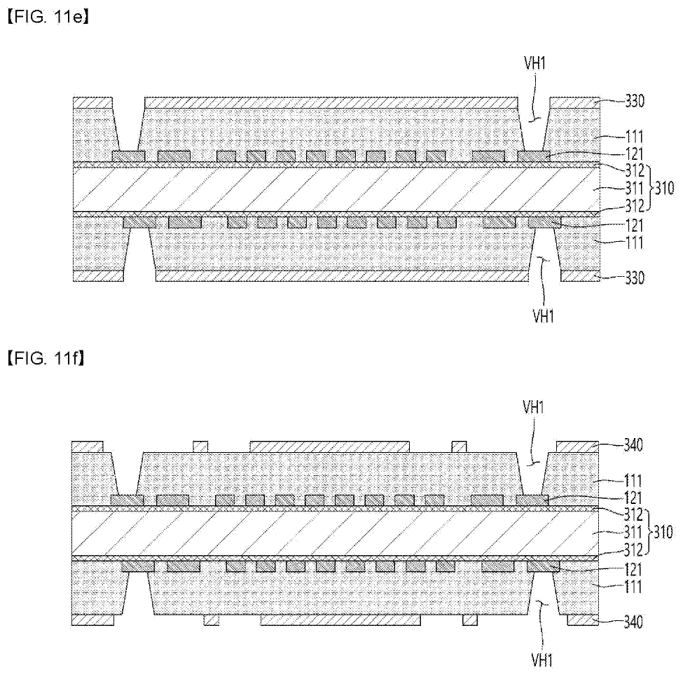

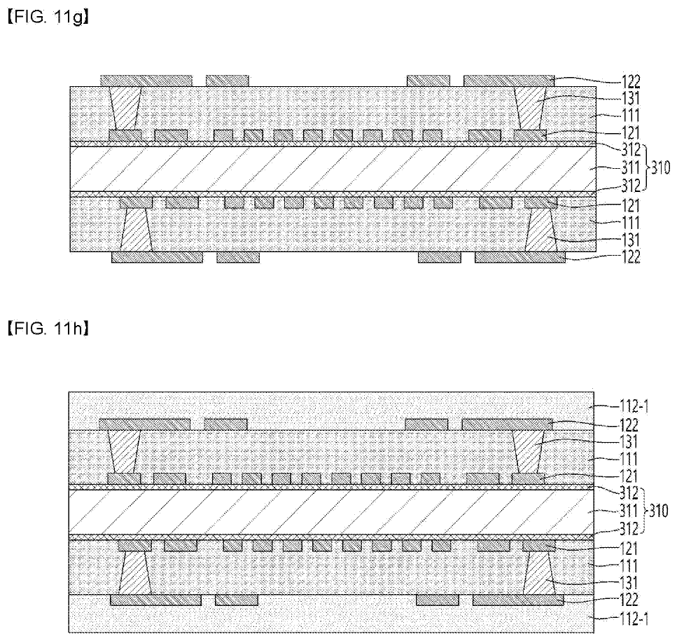

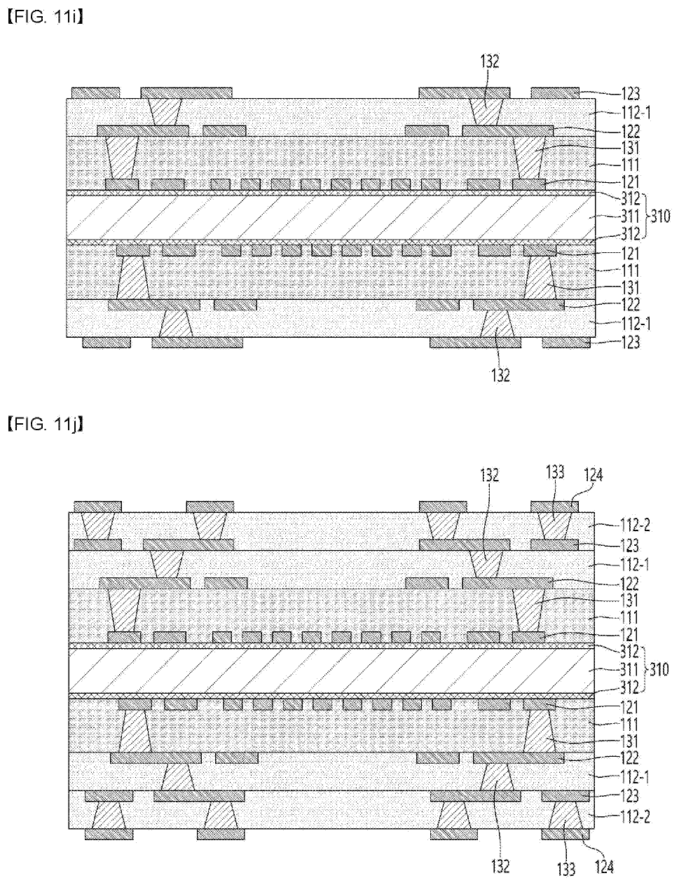

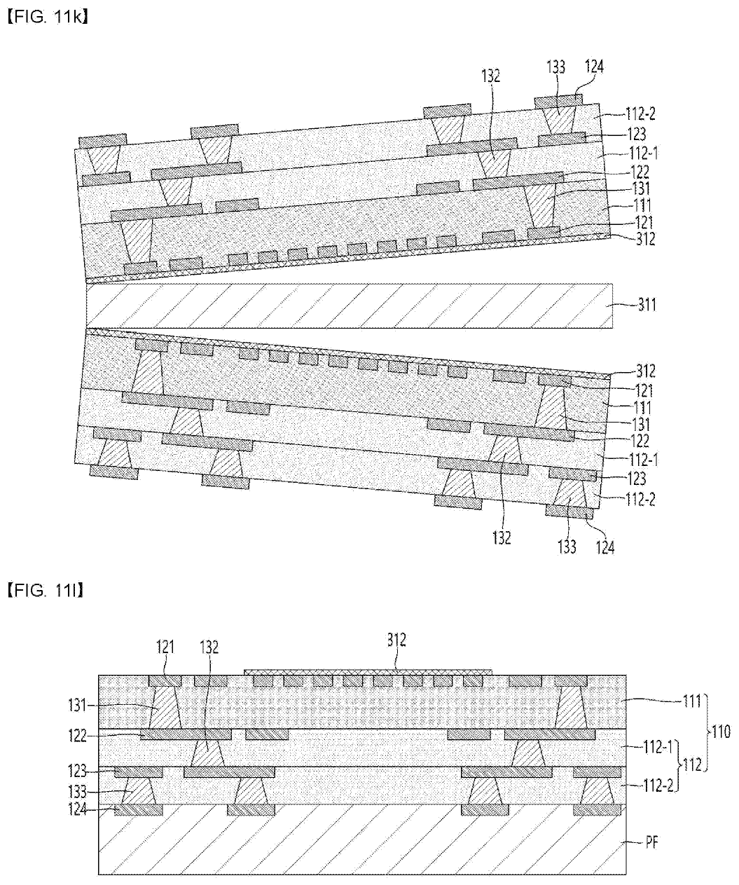

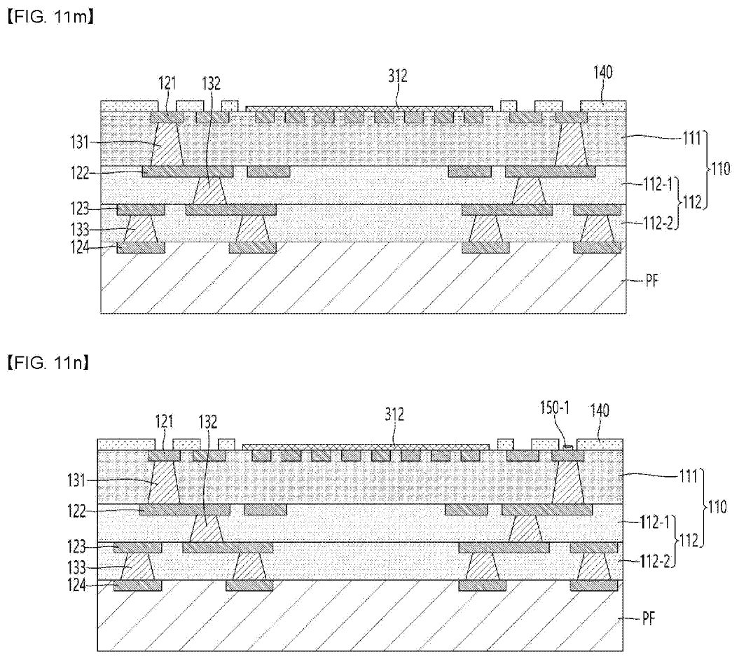

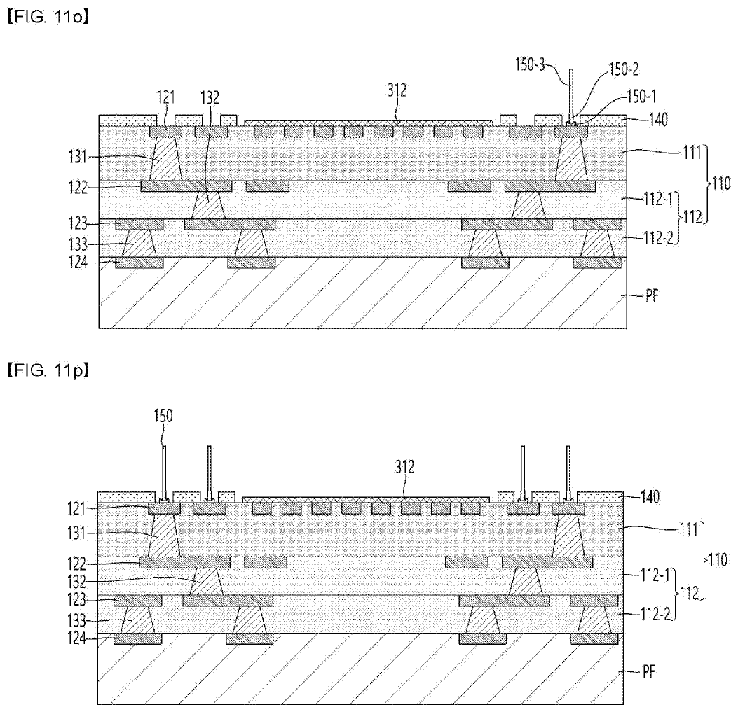

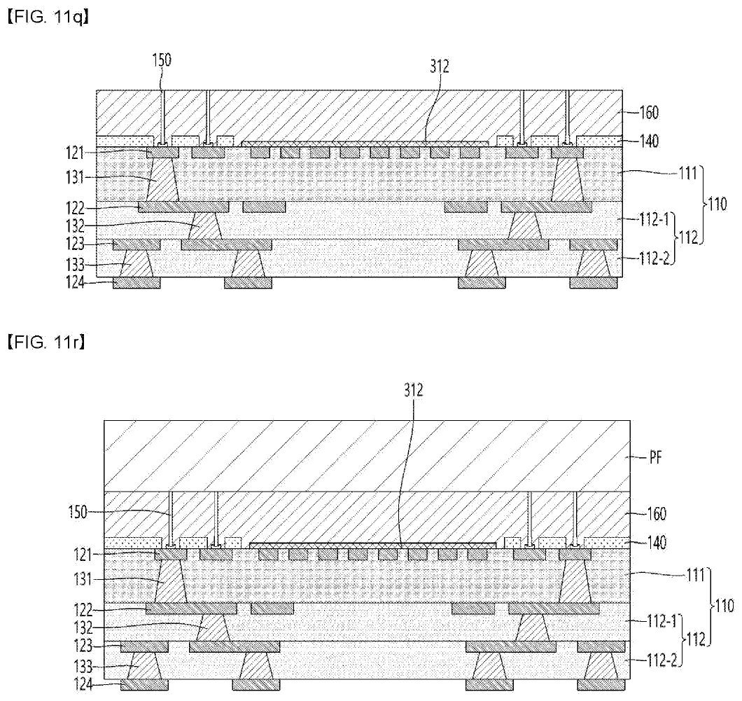

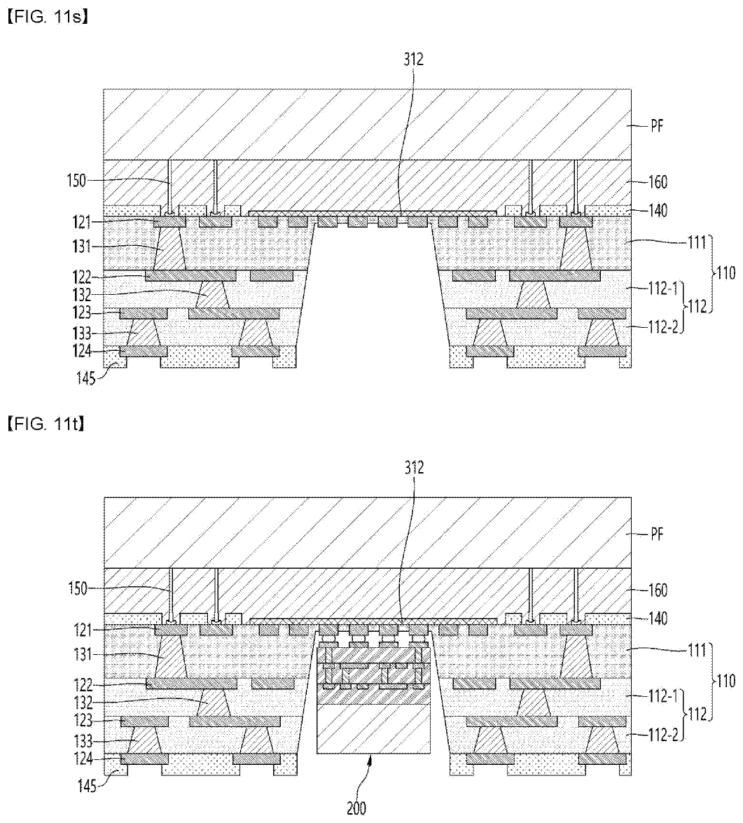

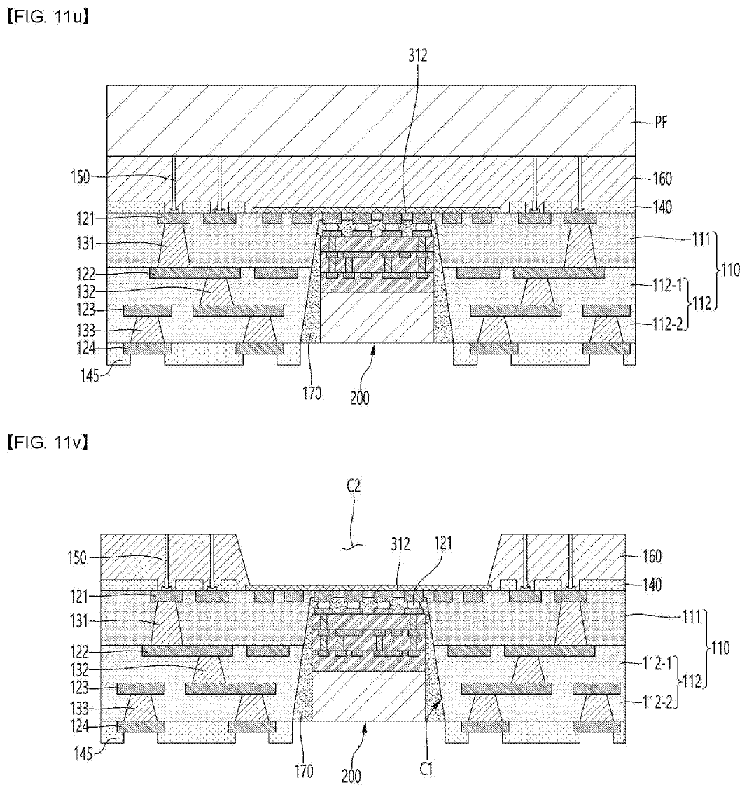

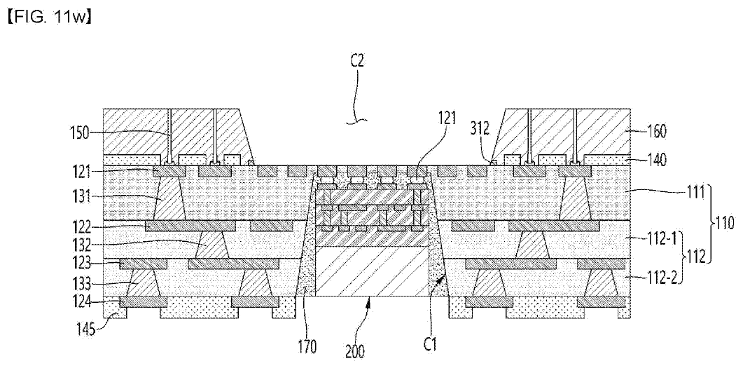

FIGS. 11A to 11W are views for explaining the circuit board of FIG. 2 in order of process.

Referring to FIG. 11A, the circuit board in the embodiment may be manufactured using a ETS method. To this end, the embodiment may perform with a process of preparing a basic material for manufacturing a circuit board. To this end, the embodiment may prepare a carrier board 310. The carrier board 310 may include a carrier insulating layer 311 and a carrier metal layer 312 disposed on at least one surface of the carrier insulating layer 311.

And, the embodiment may perform with a process of simultaneously manufacturing two circuit boards on both sides of the carrier board 310 using the carrier metal layer 312 disposed on both sides thereof.

The carrier metal layer 312 may be formed by electroless plating on the carrier insulating layer 311. In addition, the embodiment may use CCL (Copper Clad Laminate) as the carrier board 310.

Subsequently, as shown in FIG. 11B, the embodiment may perform with a process of forming a first mask 320 on the carrier metal layer 312. At this time, the first mask 320 may be formed to completely cover the carrier metal layer 312, and may include an opening (not shown) formed through a process of opening it later and overlapping the surface of the carrier metal layer 312 in a vertical direction. That is, the first mask 320 may include an opening (not shown) for opening a region in which the first circuit pattern 121 is to be formed on the surface of the carrier metal layer 312.

Subsequently, as shown in FIG. 11C, a process of forming the first circuit pattern 121 filling the opening of the first mask 320 of the embodiment may be performed by performing electroplating using the carrier metal layer 312 as a seed layer.

Subsequently, as shown in FIG. 11D, the embodiment may perform with a process of removing the first mask 320 disposed on the carrier metal layer 312. In addition, the embodiment may perform with a process of forming the first insulating layer 111 covering the first circuit pattern 121 on the carrier metal layer 312. The first insulating layer 111 may include a prepreg.

Subsequently, as shown in FIG. 11E, the embodiment may perform with a process of forming a via hole VH1 in the first insulating layer 111. The via hole VH1 may be formed through a laser process to open a resin and a reinforcing fiber constituting the first insulating layer 111. To this end, a process of forming a second mask 330 (e.g., a laser mask) for forming the via hole VH1 through the laser process may be performed on the first insulating layer 111.

Subsequently, as shown in FIG. 11F, the embodiment may perform with a process of forming a third mask 340 on a surface of the first insulating layer 111 and the via hole VH1. In this case, the third mask 340 may include at least one opening (not shown). For example, the third mask 340 may include an opening that vertically overlaps with the region where the first via 131 is to be formed and an opening that vertically overlaps with the second circuit pattern 122.

Subsequently, as shown in FIG. 11G, the embodiment may perform with a process of forming the first via 131 and the second circuit pattern 122 by performing electroplating to fill the opening of the third mask 640. When the first via 131 and the second circuit pattern 122 are formed, a process of removing the third mask 640 may be performed.

Subsequently, as shown in FIG. 11H, the embodiment may perform with a process of forming a second-first insulating layer 112-1 on the first insulating layer 111. In this case, the second-first insulating layer 112-1 may be formed of RCC. In addition, the RCC may include a copper foil layer (not shown), and the copper foil layer may be removed through an etching process.

Subsequently, as shown in FIG. 11I, the embodiment may perform with a process of forming the second via 132 and the third circuit pattern 123 in the second-first insulating layer 112-1.

Subsequently, as shown in FIG. 11J, the embodiment may perform with a process of forming a second-second insulating layer 112-2 on the second-first insulating layer 112-1. In addition, the embodiment may perform with a process of forming the third via 133 and the fourth circuit pattern 124 in the second-second insulating layer 112-2.

Subsequently, as shown in FIG. 11K, when the manufacture of the circuit board is completed as described above, a process of separating the circuit boards manufactured from both sides of the carrier board 310 may be performed. In this case, it may be possible to easily separate the carrier insulating layer 311 and the carrier metal layer 312 of the carrier board 310 of the embodiment. Accordingly, the carrier metal layer 312 may remain on an outermost side of the circuit board as the separation process performs. The carrier metal layer 312 is a seed layer used to form the first circuit pattern 121 as described above.

Subsequently, referring to FIG. 11L, the embodiment may perform with a process of etching and removing the carrier metal layer 312 used as the seed layer. To this end, the embodiment may perform with a process of forming the first protective film PF on the second surface or the lower surface of the second-second insulating layer 112-2. The first protective film PF may be a protective layer for protecting the second-second insulating layer 112-2 and the fourth circuit pattern 124 in a subsequent process performed on the upper side of the first insulating layer 111.

Meanwhile, the embodiment may perform with a process of forming a cavity during a manufacturing process of a circuit board. The cavity may include a first cavity C1 and a second cavity C2. In this case, the first cavity C1 and the second cavity C2 may be formed through a laser process. In addition, a laser stopper for forming a cavity to a desired depth must exist in order to proceed with the laser process. In this case, a part of the carrier metal layer 312 in the embodiment is used as the laser stopper. Accordingly, the embodiment may omit the process of additionally forming the laser stopper, thereby simplifying the manufacturing process and thus reducing the manufacturing cost.

Accordingly, the embodiment may perform with a process of removing only the remaining portions while leaving the portions located in the regions where the first and second cavities C1 and C2 are to be formed during the etching process of the carrier metal layer 312. Hereinafter, a part of the carrier metal layer 312 that is not removed will be referred to as a ‘stopper’.

Next, as shown in FIG. 11M, the embodiment may perform with a process of forming a first protective layer 140 on an upper surface of the first insulating layer 111. In this case, the first protective layer 140 may be disposed on an entire region of an upper surface of the first insulating layer 111. Further, the embodiment may perform with a process of forming an opening overlapping a region corresponding to the third pad 121-3 in a vertical direction by processing the first protective layer 140. In this case, the first protective layer 140 may include an opening that vertically overlaps with the first region R1 of the upper surface of the first insulating layer 111. Here, the first region R1 may be a region in which the stopper 312 is disposed.

Next, the embodiment may perform with a process of forming a through electrode 150 on the upper surface of the third pad 121-3 overlapping the opening of the first protective layer 140 in the vertical direction. In this case, the through electrode 150 may be performed using wire bonding equipment (not shown). For example, the through electrode 150 may be formed by bonding a metal wire to the upper surface of the third pad 121-3 using wire bonding equipment.

Meanwhile, the through electrodes 150 may be respectively formed on the plurality of third pads 121-3. To this end, the first protective layer 160 may include a plurality of openings vertically overlapping with the upper surface of the third pad 121-3 on which the through electrode 150 is to be disposed among the first circuit patterns 121.

In addition, the embodiment may perform with a process of forming the through electrode 150 on each of the third pads 121-3 overlapping the opening of the first protective layer 160 in the vertical direction.

To this end, the embodiment may perform with a process of forming a first conductive coupling part 150-1 corresponding to the wire ball on the third pad 121-3 using wire bonding equipment.

Next, as shown in FIG. 11O, the embodiment may perform with a process of forming the reinforcing part 150-2 on the first conductive coupling part 150-1. That is, the embodiment may perform with a process of pulling out the metal wire in an upward direction after the first conductive coupling part 150-1 is formed. In this case, the embodiment may perform with the process of forming the reinforcing part 150-2 in order to increase the strength of the through electrode 150 in the process of pulling out the metal wire. The reinforcing part 150-2 is formed by pressing the metal wire in a downward direction, and thus may have a width greater than a width of the metal wire. For example, the reinforcing part 150-2 may be referred to as a stepped part disposed between the first conductive coupling part 150-1 and the through part 150-3 of the through electrode 150.

Thereafter, the embodiment may perform with a process of forming the through part 150-3 having a width corresponding to a diameter of the metal wire by pulling out the metal wire for a long time on the reinforcing part 150-2 as the reinforcement part 150-2 is formed. In this case, the embodiment may control a width and a height of the first conductive coupling part 150-1 and a width and a height of the reinforcing part 150-2 correspond to the overall height of the through electrode 150. Accordingly, the through part 150-3 of the through electrode 150 in the embodiment is supported by the reinforcing part 150-2 while having a straightness of at least a certain level so that it can be stably disposed.

In the embodiment, the through electrodes 150 having a predetermined height may be formed on the plurality of third pads 121-3 by repeating the above process.

Next, as shown in FIG. 11Q, the embodiment may perform a process of forming the second molding layer 160 on the first protective layer 140 and the stopper 312. The second molding layer 160 may be formed to protect the through electrode 150 and to protect the upper side of the first insulating layer 111 during the insertion process of the bridge substrate 200.

In this case, a width of the opening of the first protective layer 160 may be greater than the width of the first conductive coupling part 150-1 of the through electrode 150. Accordingly, the second molding layer 160 may be formed to fill the opening of the first protective layer 160. Through this, the first conductive coupling part 150-1, the reinforcing part 150-2 and the through electrode 150 of the through electrode 150 in the embodiment may be covered by the second molding layer 160.

Here, the second molding layer 160 in the embodiment may be formed to cover an upper portion of the through electrode 150 in the process of forming the second molding layer 160. For example, the second molding layer 160 may be positioned higher than an upper surface of the through part 150-3 of the through electrode 150, and the through electrode 150 may be buried based thereon. Thereafter, the embodiment may perform with a process of planarizing a part of the second molding layer 160 by grinding, and accordingly, an upper surface of the second molding layer 160 and an upper surface of the through electrode 150 may be positioned on the same plane.

Next, as shown in FIG. 11R, the embodiment may perform with a process of removing the first protective film PF. Thereafter, the embodiment may perform with a process of forming the second protective film PF on the second molding layer 160. In addition, the embodiment may perform with a process of forming the second protective layer 145 on a lower surface of the second-second insulating layer 112-2. The second protective layer 145 may include a region in which the first cavity C1 is to be formed and an opening that vertically overlaps with a lower surface of a terminal pad of the fourth circuit pattern 122.

Next, as shown in FIG. 11S, the embodiment may perform with a process of forming the first cavity C1 by processing the first insulating layer 111 and the second insulating layer 112. The first cavity C1 may overlap a lower surface of the first-second pad 121-12 and a lower surface of the second-second pad 121-22 of the first circuit pattern 121 disposed on the upper surface of the first insulating layer 111 in a vertical direction. At this time, a part of the first insulating layer 111 disposed on the side surfaces of the first-second pad 121-12 and the second-second pad 121-22 of the embodiment is allowed to remain by adjusting a laser processing conditions.

Next, as shown in FIG. 11T, the embodiment may perform with a process of manufacturing the bridge substrate 200. At this time, since the manufacturing process of the bridge substrate 200 has already been described above, a detailed description thereof will be omitted. Thereafter, when the bridge substrate 200 is manufactured, the embodiment may perform with a process of attaching the third conductive coupling part 201 on the pad layer 250 of the bridge substrate 200. Thereafter, the embodiment may perform with a process of attaching the bridge substrate 200 to a lower surface of the first-second pad 121-12 and a lower surface of the second-second pad 121-22 overlapping the first cavity C1 in the vertical direction using the third conductive coupling part 201.

Next, as shown in FIG. 11U, the embodiment may perform with a process of forming the first molding layer 170 filling the first cavity C1. The first molding layer 170 may serve to protect the bridge substrate 200 disposed in the first cavity C1. As shown in the drawings, the first molding layer 170 may expose a lower surface of the base layer 210 of the bridge substrate 200 to the outside of the substrate. However, the embodiment is not limited thereto, and the first molding layer 170 may cover all up to the base layer 210 of the bridge substrate 200.

Next, as shown in FIG. 11V, the embodiment may perform with a process of removing the second protective film PF. Thereafter, the embodiment may perform with a process of forming the second cavity C2 by laser processing the second molding layer 160. At this time, a stopper 312 is formed in the region where the second cavity C2 is to be formed, and accordingly, the embodiment may perform a process of forming the second cavity C2 by removing the region where the stopper 312 is formed from the second molding layer 160. As the second cavity C2 is formed, the second cavity C2 may vertically overlap the stopper 312 buried in the second molding layer 160.

In this case, the width of the stopper 312 may be greater than the width of the lower surface of the second cavity C2. Accordingly, an upper surface of at least a part of the stopper 312 may not overlap the second cavity C2 in a vertical direction.

Next, as shown in FIG. 11W, the embodiment may perform with a process of etching and removing the stopper 312 overlapping the second cavity C2 in the vertical direction as the second cavity C2 is formed. Accordingly, the second cavity C2 of the embodiment may vertically overlap the upper surfaces of the first pad 121-1 and the second pad 121-2 of the first circuit pattern 121.

In this case, at least a part of the stopper 312 may remain between the first insulating layer 111 and the second molding layer 160. However, the embodiment is not limited thereto, and an additional process for completely removing the stopper may be performed.

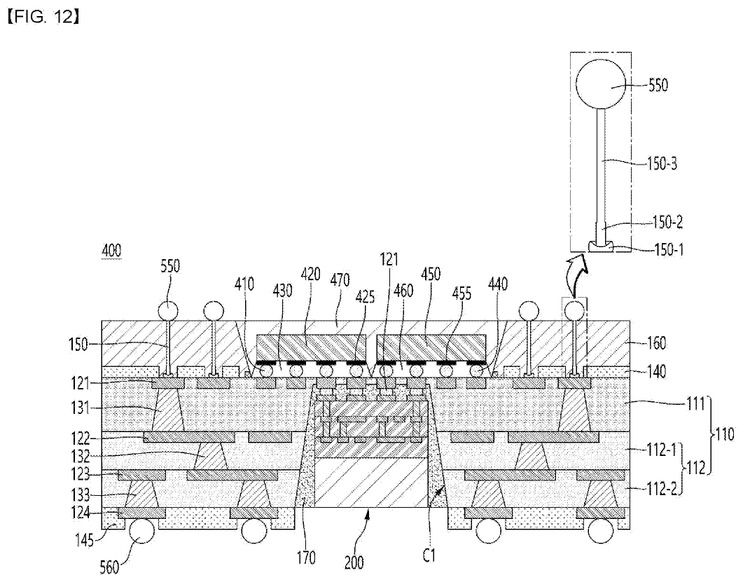

FIG. 12 is a view illustrating a first semiconductor package according to an embodiment.

The first semiconductor package may refer to a first package in which the first processor chip and the second processor chip are mounted on the circuit board shown in FIGS. 2 and 9.

Referring to FIG. 12, the first semiconductor package 400 in the embodiment may be manufactured by mounting the first chip and the second chip on the circuit board shown in FIGS. 2 and 9.

The first semiconductor package 400 may include a circuit board and a first chip 420 and a second chip 450 mounted on the circuit board. Since the circuit board has already been described above, a detailed description thereof will be omitted.

In the embodiment, the first circuit pattern 121 disposed on the outermost side of the circuit board is included. In addition, the first circuit pattern 121 includes a first pad 121-1 and a second pad 121-2.

In addition, the first semiconductor package 400 may include a fourth conductive coupling part 410 disposed on the upper surface of the first pad 121-1. Also, the first semiconductor package 400 may include a fifth conductive coupling part 440 disposed on the upper surface of the second pad 121-2.

The fourth conductive coupling part 410 and the fifth conductive coupling part 440 may have the same shape or different shapes.

For example, the fourth conductive coupling part 410 and the fifth conductive coupling part 440 may have a hexahedral shape. For example, cross-sections of the fourth conductive coupling part 410 and the fifth conductive coupling part 440 may include a rectangular shape. Cross-sections of the fourth conductive coupling part 410 and the fifth conductive coupling part 440 may include a rectangle or a square shape. For example, the fourth conductive coupling part 410 and the fifth conductive coupling part 440 may have a spherical shape. For example, cross-sections of the fourth conductive coupling part 410 and the fifth conductive coupling part 440 may include a circular shape or a semicircular shape. For example, cross-sections of the fourth conductive coupling part 410 and the fifth conductive coupling part 440 may include a partially or entirely rounded shape. Cross-sectional shapes of the fourth conductive coupling part 410 and the fifth conductive coupling part 440 may be flat on one side and curved on the other side. The fourth conductive coupling part 410 and the fifth conductive coupling part 440 may be solder balls, but are not limited thereto.

In an embodiment, the first chip 420 may be disposed on the fourth conductive coupling part 410. The first chip 420 may be a first processor chip. For example, the first chip 420 may be an application processor (AP) chip among a central processor (e.g., CPU), a graphic processor (e.g., GPU), a digital signal processor, an encryption processor, a microprocessor, and a microcontroller. A terminal 425 of the first chip 420 may be electrically connected to the first pad 121-1 through the fourth conductive coupling part 410.

In addition, the second chip 450 in an embodiment may be disposed on the fifth conductive coupling part 440. The second chip 450 may be a second processor chip. For example, the second chip 450 may include an application processor (AP) chip of a different type from that of the first chip 420 among a central processor (e.g., CPU), a graphic processor (e.g., GPU), a digital signal processor, an encryption processor, a microprocessor, and a microcontroller. A terminal 455 of the second chip 450 may be electrically connected to the second pad 121-2 through the fifth conductive coupling part 440.

For example, the first chip 420 may be a central processor chip, and the second chip 450 may be a graphics processor chip, but is not limited thereto.

Meanwhile, the first chip 420 and the second chip 450 may be spaced apart from each other by a predetermined distance on the circuit board. For example, the distance between the first chip 420 and the second chip 450 may be 150 μm or less. For example, the distance between the first chip 420 and the second chip 450 may be 120 μm or less. For example, the distance between the first chip 420 and the second chip 450 may be 100 μm or less.

Preferably, the distance between the first chip 420 and the second chip 450 may be in a range of 60 μm to 150 μm. Preferably, the distance between the first chip 420 and the second chip 450 may be in a range of 70 μm to 120 μm. Preferably, the distance between the first chip 420 and the second chip 450 may be in a range of 80 μm to 110 μm. When the distance between the first chip 420 and the second chip 450 is less than 60 μm, a region in which the bridge substrate 200 is disposed may not be secured. In addition, when the distance between the first chip 420 and the second chip 450 is less than 60 μm, a problem may occur in operation reliability of the first chip 420 or the second chip 450 due to the interference between the first chip 420 and the second chip 450.

When the distance between the first chip 420 and the second chip 450 is greater than 150 μm, signal transmission loss may increase as the distance between the first chip 420 and the second chip 450 increases. When the distance between the first chip 420 and the second chip 450 is greater than 150 μm, the volume of the first semiconductor package 400 may increase.

The first semiconductor package 400 may include a first fillet layer 430 and a second fillet layer 460. The first fillet layer 430 may be disposed to surround a terminal 425 of the first chip 420. The first fillet layer 430 may prevent foreign substances (e.g., moisture) from penetrating into the space between the circuit board and the first chip 420. The second fillet layer 460 may be disposed to surround the terminal 455 of the second chip 450. The second fillet layer 460 may prevent foreign substances (e.g., moisture) from penetrating into the space between the circuit board and the second chip 450.

The first semiconductor package 400 may include a third molding layer 470. The third molding layer 470 may be disposed to cover the first chip 420 and the second chip 450. For example, the third molding layer 470 may be an epoxy mold compound (EMC) formed to protect the mounted first chip 420 and the second chip 450, but is not limited thereto. The third molding layer 470 may be disposed to fill the second cavity C2 of the circuit board.

The third molding layer 470 may have a low dielectric constant to stably protect the first chip 420 and the second chip 450 while improving heat dissipation characteristics. For example, the dielectric constant Dk of the third molding layer 470 may be 0.2 to 10. For example, the dielectric constant Dk of the third molding layer 470 may be 0.5 to 8. For example, the dielectric constant Dk of the third molding layer 470 may be 0.8 to 5. Accordingly, the third molding layer 470 in the embodiment has a low dielectric constant, so that heat dissipation characteristics against heat generated by the first chip 420 and/or the second chip 450 can be improved.

Also, the second molding layer 160 and the third molding layer 470 in an embodiment may include different materials. The second molding layer 160 may be used to protect the through electrode 150, and the third molding layer 470 may be used to protect the first chip 420 and the second chip 450. Accordingly, the second molding layer 160 and the third molding layer 470 may have different strengths. As described above, the embodiment can stably protect the through electrode 150 and the first chip 420 and the second chip 450 by forming the second molding layer 160 and the third molding layer 470 of different materials. In addition, the embodiment can protect the circuit board from damage when the bridge substrate 200 is mounted, as the manufacturing process of the circuit board is performed in the state in which the second molding layer 160 is formed, furthermore, the reliability of the connection between the circuit board and the bridge substrate 200 may be improved.

Meanwhile, the first semiconductor package 400 may include a second conductive coupling part 550 disposed on the through electrode 150. The second conductive coupling part 550 may be formed to attach a second semiconductor package (e.g., a memory substrate) on the first semiconductor package 400.

The second conductive coupling part 550 may directly contact the upper surface of the through part 150-3 of the through electrode 150. In this case, the through part 150-3 in an embodiment is a part formed through a metal wire, and thus may have a width corresponding to the diameter of the metal wire. In addition, the embodiment may reduce the width or diameter of the second conductive coupling part 550 compared to the comparative example by disposing the second conductive coupling part 550 on the through electrode 150. That is, a solder ball of the comparative example is disposed directly on the pad or disposed on the metal post, and accordingly, the width of the solder ball was at least 110 μm or more. On the other hand, in the embodiment, the width of the second conductive coupling part 550 may be reduced to less than 110 μm by disposing the second conductive coupling part 550 on the through electrode 150.

Meanwhile, a size corresponding to the width or diameter of the second conductive coupling part 550 may be larger than a size corresponding to the width or diameter of the first conductive coupling part 150-1 constituting the through electrode 150. For example, the size of the first conductive coupling part 150-1 may be smaller than the size of the second conductive coupling part 550.

In addition, the first semiconductor package 400 includes a sixth conductive coupling part 560 disposed on the fourth circuit pattern 124 overlapping the opening of the second protective layer 145 of the circuit board in a vertical direction. The sixth conductive coupling part 560 may be an adhesive ball connected to the main board of the electronic device.

The sixth conductive coupling part 560 may be larger than the sizes of the first conductive coupling part 150-1 and the second conductive coupling part 550.

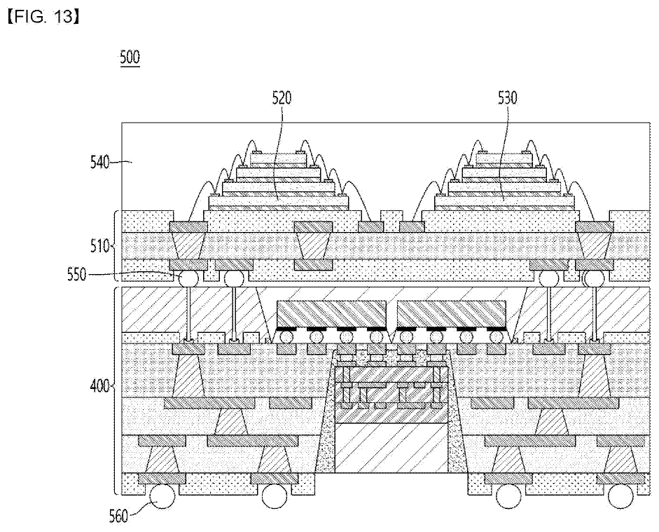

FIG. 13 is a view illustrating a second semiconductor package according to an embodiment.

Referring to FIG. 13, the second semiconductor package 500 may be a substrate in which a second package corresponding to a memory chip package is coupled to the first package 400 of FIG. 12.

To this end, the second semiconductor package 500 may include a memory chip package.

The memory chip package includes a memory substrate 510. The memory substrate 510 may include at least one insulating layer, a via layer, a circuit pattern layer, and a protective layer. The memory substrate 510 is substantially the same as the third substrate of the comparative example, and thus a detailed description thereof will be omitted.

The memory chip package includes a memory chip mounted on the memory substrate 510. For example, the memory chip package may include a first memory chip 520 and a second memory chip 530 mounted on the memory substrate 510 with a predetermined interval therebetween.

In addition, the memory chip package may include a fourth molding layer 540 disposed on the memory substrate 510 and molding the first memory chip 520 and the second memory chip 530.

Meanwhile, the second semiconductor package 500 may be attached to the first semiconductor package 400 through the second conductive coupling part 550 disposed on the through electrode 150 of the first semiconductor package 400.

A thickness of the second semiconductor package 500 as described above may be reduced compared to the semiconductor package of the comparative example.

The thickness of the semiconductor package 500 in the embodiment may be smaller than the thickness (t8+t9) of the semiconductor package in the comparative example. The thickness of the semiconductor package 500 may be 95% of the thickness (t8+t9) of the semiconductor package of the comparative example. The thickness of the semiconductor package 500 may be 90% of the thickness (t8+t9) of the semiconductor package of the comparative example. The thickness of the semiconductor package 500 may be 85% of the thickness (t8+t9) of the semiconductor package of the comparative example.

For example, the thickness of the semiconductor package 500 may be less than 1000 μm. For example, the thickness of the semiconductor package 500 may be less than 900 μm. For example, the thickness of the semiconductor package 500 may be less than 850 μm.

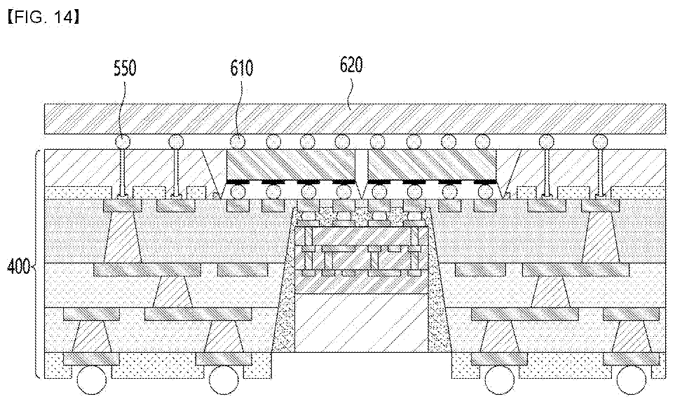

FIG. 14 is a view illustrating a third semiconductor package according to an embodiment.

Referring to FIG. 14, the third semiconductor package may have a structure in which an additional chip is disposed on the first package 400 illustrated in FIG. 12.

For example, the first package 400 includes at least one chip disposed on a circuit board. For example, the first chip 420 and the second chip 450 may be mounted on a circuit board.

In addition, an additional third chip 620 in the third semiconductor package may be further mounted on the first package.

For example, the third semiconductor package may further include a third chip 620 attached to the first semiconductor package 400 through a conductive coupling part 550 disposed on the through electrode 150 of the first semiconductor package 400.

For example, a first semiconductor device may be disposed on the circuit board. A second semiconductor device may be disposed on the circuit board and the first semiconductor device. The first semiconductor device may refer to the first chip 420 and the second chip 450. The second semiconductor device may refer to the third chip 620.

In this case, the second semiconductor device 620 is connected to the through electrode 150 through the conductive coupling part 550. Through this, the second semiconductor device 620 may be connected to the circuit board through the through electrode 150.

Furthermore, a conductive coupling part 610 may also be disposed between the first semiconductor devices 420 and 450 and the second semiconductor device 620. The conductive coupling part 610 may electrically connect between the first semiconductor devices 420 and 450 and the second semiconductor device 620.

Accordingly, the second semiconductor device 620 may also be connected to the first semiconductor device through the conductive coupling part 610 while being directly connected to the circuit board including the through electrode 150 through the conductive coupling part 550.

In this case, the second semiconductor device 620 may receive a power signal through the conductive coupling part 550. In addition, the second semiconductor device 620 may transmit and receive communication signals to and from the first semiconductor device 420 and 450 through the conductive coupling part 610.

Accordingly, the third semiconductor package provides a power signal to the second semiconductor device 620 through the conductive coupling part 550, thereby providing sufficient power for driving the second semiconductor device 620. Accordingly, the embodiment may improve the driving characteristics of the second semiconductor device 620. That is, the embodiment may solve the problem of insufficient power provided to the second semiconductor device 620. That is, the driving power required by the second semiconductor device 620 may increase as a function provided by the second semiconductor device 620 has recently increased or performance has been improved. Accordingly, a power signal in the embodiment is supplied to the second semiconductor device 620 through the conductive coupling part 550. Through this, the embodiment may further improve the electrical reliability of the semiconductor package.

Furthermore, the power signal and the communication signal of the second semiconductor device 620 in the embodiment are provided through different paths. Through this, the embodiment can solve the problem that the communication signal is lost due to the power signal. For example, the embodiment may minimize mutual interference between communication signals of power signals.

The characteristics, structures, effects, and the like described in the above-described embodiments are included in at least one embodiment, but are not limited to only one embodiment. Furthermore, the characteristic, structure, and effect illustrated in each embodiment may be combined or modified for other embodiments by a person skilled in the art. Therefore, it should be construed that contents related to such combination and modification are included in the scope of the embodiment.

Embodiments are mostly described above, but the embodiments are merely examples and do not limit the embodiments, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the embodiment defined in the following claims.

1-10. (canceled)

11. A semiconductor package comprising:
an insulating layer;
an upper pad disposed on the insulating layer;
a first molding layer disposed on the insulating layer;
a through electrode including a first conductive coupling part disposed on the upper pad and having a first width in a horizontal direction, and a through part disposed on the first conductive coupling part and having a second width in the horizontal direction smaller than the first width, and passing through of the first molding layer; and
a second conductive coupling part disposed on the through part of the through electrode,
wherein the first width of the first conductive coupling part is smaller than a third width of the second conductive coupling part.

12. The semiconductor package of claim 11, wherein the through electrode includes a reinforcing part disposed between the first conductive coupling part and the through part.

13. The semiconductor package of claim 12, wherein the reinforcing part has a fourth width in the horizontal direction greater than the second width of the through part and smaller than the first width of the first conductive coupling part.

14. The semiconductor package of claim 12, wherein the reinforcing part has a width ranging between 110% and 150% of a width of the through part.

15. The semiconductor package of claim 12, wherein an upper surface of the first conductive coupling part includes a concave part concave toward the upper pad, and
wherein at least a part of the reinforcing part is disposed on the concave part of the first conductive coupling part.

16. The semiconductor package of claim 12, wherein the first conductive coupling part, the reinforcing part, and the through part are provided with the same metal material as each other, and
wherein a lower surface of the first conductive coupling part is in contact with the upper pad.

17. The semiconductor package of claim 12, wherein a height from a lower surface to an upper surface of the through electrode is in the range of 50 μm to 200 μm, and
wherein the through part has a width in a range of 10 μm to 100 μm.

18. The semiconductor package of claim 17, wherein the height of the through electrode is greater than 100 μm, and
wherein a width of the through part is greater than 40 μm.

19. The semiconductor package of claim 11, wherein the through par has a predetermined inclination with respect to an upper or lower surface of the insulating layer and passes through the first molding layer.

20. The semiconductor package of claim 19, wherein a straightness corresponding to an inclined angle of the inclination of the through part with respect to the virtual vertical line is 10 degrees or less.

21. The semiconductor package of claim 12, further comprising:
an upper protective layer disposed on the insulating layer and including a through hole overlapping the upper pad in a vertical direction,
wherein the through electrode is disposed on the upper pad overlapping the through hole of the upper protective layer in a vertical direction.

22. The semiconductor package of claim 20, wherein the first width of the first conductive coupling part of the through electrode is smaller than a width of the through hole of the upper protective layer, and
wherein the first molding layer covers at least a part of the first conductive coupling part and at least a part of the reinforcement part of the through electrode, and fills at least a part of the through hole of the upper protective layer.

23. The semiconductor package of claim 11, further comprising:
a lower pad disposed under the insulating layer;
a lower protective layer disposed under the insulating layer and including a through hole; and
a third conductive coupling part disposed in the through hole of the lower protective layer in a vertical direction,
wherein a width of the third conductive coupling part is greater than a width of the first and second conductive coupling parts.

24. The semiconductor package of claim 11, further comprising:
a mounting pad disposed on the insulating layer and spaced apart from the upper pad in the horizontal direction, wherein the first molding layer includes a first cavity overlapping at least a portion of an upper surface of the mounting pad in a vertical direction;
at least one chip mounted in the first cavity; and
a second molding layer disposed in the first cavity and molding the at least one chip.

25. The semiconductor package of claim 24, wherein the first molding layer and the second molding layer include different insulating materials.

26. The semiconductor package of claim 24, wherein the insulating layer includes a second cavity overlapping at least a portion of a lower surface of the mounting pad in the vertical direction, and
wherein a connection member is disposed in the second cavity.

27. The semiconductor package of claim 26, wherein the chip includes first and second chips spaced apart along a horizontal direction, and
wherein each of the first chip and the second chip has a terminal that overlaps the connection member in the vertical direction.

28. The semiconductor package of claim 11, wherein side and lower surfaces of the upper pad are covered by the insulating layer.

29. The semiconductor package of claim 11, wherein the insulating layer comprises a first insulating layer comprising a first insulating material including glass fibers and a second insulating layer comprising a second insulating material different from the first insulating material which does not contain glass fibers.

30. The semiconductor package of claim 11, further comprising:
a memory substrate disposed on the second conductive coupling part;
a memory chip mounted on the memory substrate; and
a third molding layer disposed on the memory substrate and covering the memory chip.
